(19) United States
(12) Patent Application Publication
(10) Pub. No.: US 2021/0118648 A1
(43) Pub. Date: Apr. 22, 2021

(54) SUBSTRATE PROCESSING SYSTEM AND METHOD FOR REPLACING EDGE RING

(71) Applicant: TOKYO ELECTRON LIMITED, Tokyo (JP)

(72) Inventor: Daisuke HAYASHI, Nirasaki City (JP)

(73) Assignee: TOKYO ELECTRON LIMITED, Tokyo (JP)

(21) Appl. No.: 17/069,411

(22) Filed: Oct. 13, 2020

(30) Foreign Application Priority Data
Oct. 18, 2019 (JP) 2019-191205

(51) Int. Cl. H01J 37/32; H01L 21/687; H01L 21/67

(52) U.S. Cl. CPC H01J 37/3288; H01L 21/68735; H01L 21/68742; H01J 2237/20235; H01L 21/67201; H01J 37/32715; H01J 37/32642; H01L 21/67196

(57) ABSTRACT

A substrate processing system allows selective replacement of one or both of two rings included in an edge ring. The substrate processing system includes a process module, a transfer robot, and a replacing module. In the process module, an edge ring is lifted from a substrate support by at least one lifter. The edge ring includes a first ring and a second ring. The edge ring is transferred between the process module and the replacing module by the transfer robot. In the replacing module, at least one of the first ring or the second ring included in the edge ring is replaced with a replacement part to prepare a replacement edge ring. The replacement edge ring is transferred between the replacing module and the process module by the transfer robot.

### CROSS-REFERENCE TO RELATED APPLICATIONS

This application claims priority to Japanese Patent Application No. 2019-191205 filed on Oct. 18, 2019, the entire disclosure of which is incorporated herein by reference.

### TECHNICAL FIELD

Exemplary embodiments of the present disclosure relate to a substrate processing system and a method for replacing an edge ring.

### BACKGROUND

Plasma processing is performed on substrates using a plasma processing apparatus. For plasma processing using a plasma processing apparatus, a substrate is placed in an area on a substrate support surrounded by an edge ring placed on the substrate support. The edge ring may also be called a focus ring.

An edge ring including multiple rings is described in Japanese Unexamined Patent Application Publication No. 2018-160666. The multiple rings include a middle ring and an outer ring. The middle ring can be raised and lowered to adjust the characteristics of plasma processing on an edge of the substrate. The edge ring can be raised and lowered with pusher pins.

### SUMMARY

At least one of a first ring or a second ring placed on the first ring included in the edge ring is to be replaced.

A substrate processing system according to an exemplary embodiment includes a process module, a transfer robot, a replacing module, and a controller. The process module includes a chamber, a substrate support, and at least one lifter. The substrate support supports an edge ring and a substrate placed in an area on the substrate support surrounded by the edge ring. The edge ring includes a first ring and a second ring. The second ring is placed on the first ring. The at least one lifter lifts the first ring and the second ring together. The transfer robot transfers the edge ring. The replacing module replaces at least one of the first ring or the second ring included in the edge ring with a replacement part to prepare a replacement edge ring. The controller controls the at least one lifter and the transfer robot. The controller controls the at least one lifter to lift the edge ring from the substrate support. The controller controls the transfer robot to transfer the edge ring lifted by the at least one lifter between the process module and the replacing module. The controller controls the transfer robot to transfer the replacement edge ring prepared in the replacing module between the replacing module and the process module.

The technique according to an exemplary embodiment allows replacement of at least one of the first ring or the second ring placed on the first ring included in the edge ring.

### BRIEF DESCRIPTION OF THE DRAWINGS

FIG. 1 is a diagram of a substrate processing system according to an exemplary embodiment.

FIG. 2 is a schematic diagram of a plasma processing apparatus according to an exemplary embodiment.

FIG. 3 is a schematic diagram of a substrate support according to the exemplary embodiment.

FIG. 4 is a partially enlarged view of the substrate support according to the exemplary embodiment.

FIG. 5 is a partially enlarged cross-sectional view of an edge ring according to the exemplary embodiment.

FIG. 6 is a partially enlarged view of the substrate support according to the exemplary embodiment.

FIG. 7 is a partially enlarged view of the substrate support according to the exemplary embodiment.

FIG. 8 is a partially enlarged view of the substrate support according to the exemplary embodiment.

FIG. 9 is a flowchart of a method for replacing an edge ring according to an exemplary embodiment.

FIGS. 10A and 10B are diagrams of a replacing module according to the exemplary embodiment.

FIG. 11 is a flowchart of a method for replacing an edge ring according to another exemplary embodiment.

FIGS. 12A, 12B, and 12C are diagrams of a replacing module according to the other exemplary embodiment.

FIGS. 13A, 13B, and 13C are diagrams of the replacing module according to the other exemplary embodiment.

FIGS. 14A, 14B, and 14C are diagrams of the replacing module according to the other exemplary embodiment.

FIG. 15 is a flowchart of a method for replacing an edge ring according to still another exemplary embodiment.

FIGS. 16A, 16B, and 16C are diagrams of a replacing module according to the other exemplary embodiment.

FIGS. 17A, 17B, and 17C are diagrams of the replacing module according to the other exemplary embodiment.

FIGS. 18A, 18B, and 18C are diagrams of the replacing module according to the other exemplary embodiment.

FIGS. 19A, 19B, and 19C are diagrams of the replacing module according to the other exemplary embodiment.

FIGS. 20A and 20B are diagrams of the replacing module according to the other exemplary embodiment.

FIGS. 21A, 21B, and 21C are diagrams of the replacing module according to the other exemplary embodiment.

FIGS. 22A and 22B are diagrams of the replacing module according to the other exemplary embodiment.

FIG. 23 is a diagram of a substrate processing system according to another exemplary embodiment.

FIG. 24 is a diagram of a substrate processing system according to still another exemplary embodiment.

FIG. 25 is a flowchart of a method for replacing an edge ring according to still another exemplary embodiment.

FIGS. 26A, 26B, and 26C are diagrams of a replacing module according to the other exemplary embodiment.

FIGS. 27A and 27B are diagrams showing first and second storage areas located at a load port, and FIG. 27C is a diagram of the replacing module according to the other exemplary embodiment.

FIGS. 28A, 28B, and 28C are diagrams of the replacing module according to the other exemplary embodiment.

FIG. 29 is a diagram of a substrate processing system according to still another exemplary embodiment.

### DETAILED DESCRIPTION

Exemplary embodiments will now be described.

A substrate processing system according to one exemplary embodiment includes a process module, a transfer robot, a replacing module, and a controller. The process module includes a chamber, a substrate support, and at least one lifter. The substrate support supports an edge ring and a substrate placed in an area on the substrate support surrounded by the edge ring. The edge ring includes a first ring and a second ring. The second ring is placed on the first ring. The at least one lifter lifts the first ring and the second ring together. The transfer robot transfers the edge ring. The replacing module replaces at least one of the first ring or the second ring included in the edge ring with a replacement part to prepare a replacement edge ring. The controller controls the at least one lifter and the transfer robot. The controller controls the at least one lifter to lift the edge ring from the substrate support. The controller controls the transfer robot to transfer the edge ring lifted by the at least one lifter between the process module and the replacing module. The controller controls the transfer robot to transfer the replacement edge ring prepared in the replacing module between the replacing module and the process module.

In the above embodiment, both the first ring and the second ring are transferred from the process module into the replacing module. At least one of the first ring or the second ring included in the edge ring is thus replaceable in the replacing module.

In one exemplary embodiment, the substrate processing system may further include a transfer module. The transfer module is connected between the process module and the replacing module. The transfer module transfers the edge ring with the transfer robot through a chamber that is decompressed.

In one exemplary embodiment, the substrate processing system may further include a loadlock module, a loader module, and a load port. The loadlock module is connected to the transfer module. The loadlock module may serve as a preliminary decompression chamber. The loader module transfers the edge ring through a housing having an atmospheric pressure. The load port is connected to the loader module. The replacing module may include a lifter that lifts the second ring above the first ring. In this embodiment, the controller controls the lifter included in the replacing module to lift the second ring included in the edge ring transferred into the replacing module above the first ring included in the edge ring. The controller controls the transfer robot to transfer the second ring lifted by the lifter included in the replacing module into the loadlock module. The controller controls the loader module to transfer the second ring transferred into the loadlock module to the load port. The controller controls the transfer robot to transfer the replacement edge ring prepared by the second ring being replaced with a replacement part in the replacing module between the replacing module and the process module.

In one exemplary embodiment, the replacing module may include a lifter, a first storage area, and a second storage area. The lifter included in the replacing module lifts the second ring above the first ring. The first storage area stores the second ring included in the edge ring transferred from the process module. The second storage area stores a replacement part to replace the second ring. In this embodiment, the controller controls the lifter included in the replacing module to lift the second ring included in the edge ring transferred into the transfer module above the first ring included in the edge ring. The controller controls the transfer robot to store the second ring lifted by the lifter included in the replacing module into the first storage area. The controller controls the transfer robot to transfer the replacement edge ring including the first ring included in the edge ring transferred into the replacing module and the replacement part retrieved from the second storage area between the replacing module and the process module.

In one exemplary embodiment, the replacing module may be directly connected to the process module. In one exemplary embodiment, the replacing module may include a lifter, a first storage area, and a second storage area. The lifter included in the replacing module lifts the second ring above the first ring. The first storage area stores the second ring included in the edge ring transferred from the process module. The second storage area stores a replacement part to replace the second ring. In this embodiment, the controller controls the lifter included in the replacing module to lift the second ring included in the edge ring transferred into the transfer module above the first ring included in the edge ring. The controller controls the transfer robot to store the second ring lifted by the lifter included in the replacing module into the first storage area. The controller controls the transfer robot to transfer the replacement edge ring including the first ring included in the edge ring transferred into the replacing module and the replacement part retrieved from the second storage area between the replacing module and the process module.

In one exemplary embodiment, the replacing module may further include a third storage area and a fourth storage area. The third storage area stores the first ring included in the edge ring transferred from the process module. The fourth storage area stores a replacement part to replace the first ring. In this embodiment, the controller controls the lifter included in the replacing module to lift the second ring included in the edge ring transferred into the transfer module above the first ring included in the edge ring. The controller controls the transfer robot to store the second ring lifted by the lifter included in the replacing module into the first storage area. The controller controls the transfer robot to store the first ring included in the edge ring transferred into the replacing module into the third storage area. The controller controls the transfer robot to transfer the replacement edge ring between the replacing module and the process module. The replacement edge ring includes the replacement part retrieved from the fourth storage area and one of the second ring stored in the first storage area or the replacement part retrieved from the second storage area.

In one exemplary embodiment, the substrate processing system may further include a loader module and a load port. The loader module transfers the edge ring through a housing having an atmospheric pressure. The load port is connected to the loader module. The replacing module may be a loadlock module connected to the transfer module. The replacing module may include a lifter that lifts the second ring above the first ring. The load port includes a first storage area and a second storage area. The first storage area stores the second ring included in the edge ring transferred from the process module. The second storage area stores a replacement part to replace the second ring. In this embodiment, the controller controls the lifter included in the replacing module to lift the second ring included in the edge ring transferred into the placing module above the first ring included in the edge ring. The controller controls the loader module to store the second ring lifted by the lifter included in the replacing module into the first storage area. The controller controls the loader module to transfer the replacement part from the second storage area into the replacing module. The controller controls the transfer robot to transfer the replacement edge ring including the first ring included in the edge ring transferred into the replacing module and the replacement part transferred from the second storage area between the replacing module and the process module.

In one exemplary embodiment, the substrate processing system may further include a loadlock module and a loader module. The loadlock module is connected to the transfer module. The loader module transfers the edge ring through a housing having an atmospheric pressure. The replacing module may be connected to the loader module. The replacing module may include a lifter, a first storage area, and a second storage area. The lifter included in the replacing module lifts the second ring above the first ring. The first storage area stores the second ring included in the edge ring transferred from the process module. The second storage area stores a replacement part to replace the second ring. In this embodiment, the controller controls the lifter included in the replacing module to lift the second ring included in the edge ring transferred into the transfer module above the first ring included in the edge ring. The controller controls the loader module to store the second ring lifted by the lifter included in the replacing module into the first storage area. The controller controls the transfer robot to transfer the replacement edge ring including the first ring included in the edge ring transferred into the replacing module and the replacement part retrieved from the second storage area between the replacing module and the process module.

A method for replacing an edge ring according to another exemplary embodiment includes lifting an edge ring including a first ring and a second ring from a substrate support with at least one lifter in a chamber in a process module. The method further includes transferring the edge ring lifted by the at least one lifter between the process module and a replacing module with a transfer robot. The method further includes replacing at least one of the first ring or the second ring included in the edge ring with a replacement part to prepare a replacement edge ring in the replacing module. The method further includes transferring the replacement edge ring between the replacing module and the process module with the transfer robot.

Exemplary embodiments will now be described in detail with reference to the drawings. In the drawings, similar or corresponding components are indicated by like reference numerals. The embodiments are illustrated by way of example and not by way of limitation in the accompanying drawings that are not to scale unless otherwise indicated.

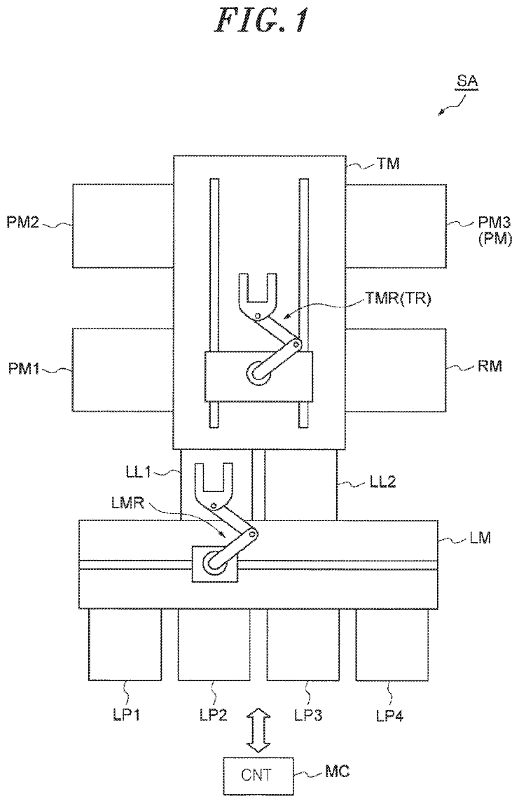

FIG. 1 is a diagram of a substrate processing system according to an exemplary embodiment. The substrate processing system shown in FIG. 1 (hereinafter referred to as the system SA) includes one or more process modules, a transfer robot TR, a replacing module RM, and a controller (CNT) MC. The system SA may further include one or more load ports, a loader module, one or more loadlock modules, and a transfer module TM. In the illustrated example, the system SA includes three process modules PM1, PM2, and PM3, four load ports LP1, LP2, LP3, and LP4, and two loadlock modules LL1 and LL2. The system SA may include any number of load ports, loadlock modules, and process modules.

The load ports LP1 to LP4 are arranged along one edge of a loader module LM. The load ports LP1 to LP4 each support a substrate container placed on the port. The substrate container may be a front-opening unified pod (FOUP). The load ports LP1 to LP4 are connected to the loader module LM.

The loader module LM includes a housing. The housing in the loader module LM has an atmospheric pressure. The loader module LM further includes a transfer robot LMR. The transfer robot LMR may be an articulated robot controlled by the controller MC. The transfer robot LMR transfers substrates between the substrate containers placed at the load ports LP1 to LP4 and the loadlock modules LL1 and LL2.

The loadlock modules LL1 and LL2 are located between the loader module LM and the transfer module TM. The loadlock modules LL1 and LL2 each are connected to the loader module LM via a gate valve. The loadlock modules LL1 and LL2 each serve as a preliminary decompression chamber. The loadlock modules LL1 and LL2 each are connected to the transfer module TM via a gate valve.

The transfer module TM includes a decompressible chamber. The transfer module TM further includes a transfer robot TMR. The transfer robot TMR may be an articulated robot controlled by the controller MC. The transfer robot TMR transfers substrates between the loadlock modules LL1 and LL2 and the process modules PM1 to PM3, and between any two of the process modules PM1 to PM3. The substrates may be transferred between the loadlock modules LL1 and LL2 and the process modules PM1 to PM3 through a decompressed space alone. The substrates may also be transferred between any two of the process modules PM1 to PM3 simply through the decompressed space.

The process modules PM1 to PM3 are connected to the transfer module TM. The process modules PM1 to PM3 are substrate processing apparatuses dedicated to intended substrate processing. One or more of the process modules PM1 to PM3 may be a plasma processing apparatus.

The replacing module RM is connected to the transfer module TM. The transfer module TM is thus connected to the process modules PM1 to PM3 and to the replacing module RM, and located between them. In one embodiment, the transfer robot TMR in the transfer module TM serves as a transfer robot TR for transferring edge rings between one of the process modules PM1 to PM3, which serves as a plasma processing apparatus, and the replacing module RM. In the replacing module RM, at least one of the first ring or the second ring in the edge ring is replaced with a replacement part to prepare a replacement edge ring.

The controller MC controls the components of the system SA. The controller MC controls, for example, the transfer robot LMR, the transfer robot TMR, and a lifter (described later) in the process module in the system SA. The controller MC may be a computer including a processor, a storage such as a memory, an input device, a display, and an input-output interface for signals. The storage in the controller MC stores control programs and recipe data. The processor in the controller MC executes the control program to control the components of the system SA in accordance with the recipe data, thus implementing the methods according to embodiments (described later).

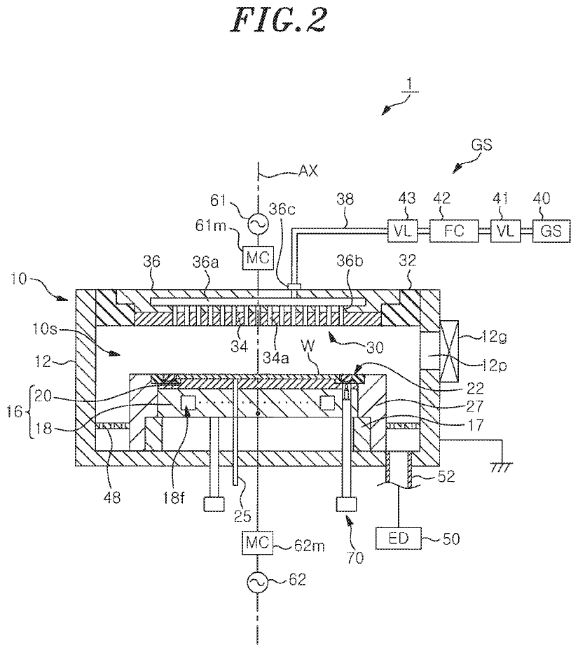

FIG. 2 is a schematic diagram of a plasma processing apparatus according to an exemplary embodiment. FIG. 2 is a partially cutaway view of the plasma processing apparatus. A plasma processing apparatus 1 in FIG. 2 may be any one of the process modules PM1 to PM3 in the system SA. The plasma processing apparatus 1 is a capacitively coupled plasma processing apparatus. The plasma processing apparatus 1 includes a chamber 10 with an internal space 10s, having a central axis AX in the vertical direction.

In one embodiment, the chamber 10 includes a chamber body 12, which is substantially cylindrical. The chamber body 12 has the internal space 10s. The chamber body 12 is formed from, for example, aluminum, and is electrically grounded. The chamber body 12 has an inner wall defining the internal space 10s, coated with a plasma-resistant film. The film may be a ceramic film, such as an anodized film or a film formed from yttrium oxide.

The chamber body 12 has a side wall having a port 12p. A substrate W is transferred between the internal space 10s and the outside of the chamber 10 through the port 12p. A gate valve 12g is on the side wall of the chamber body 12 to open and close the port 12p.

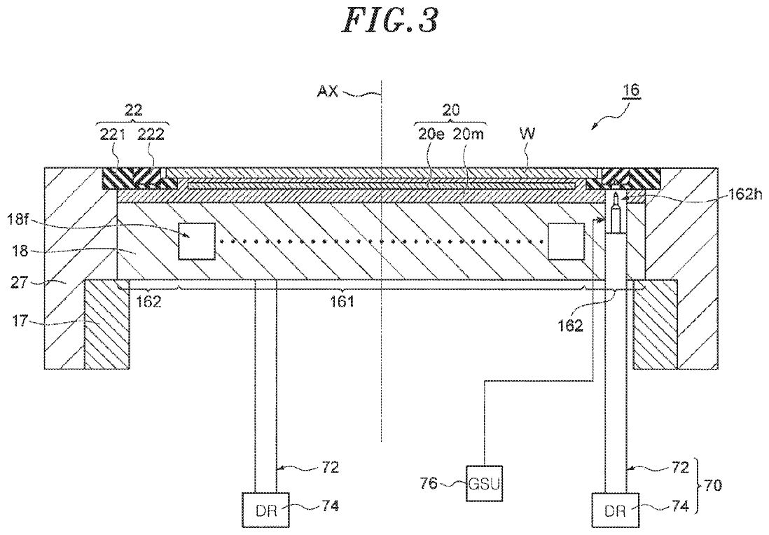

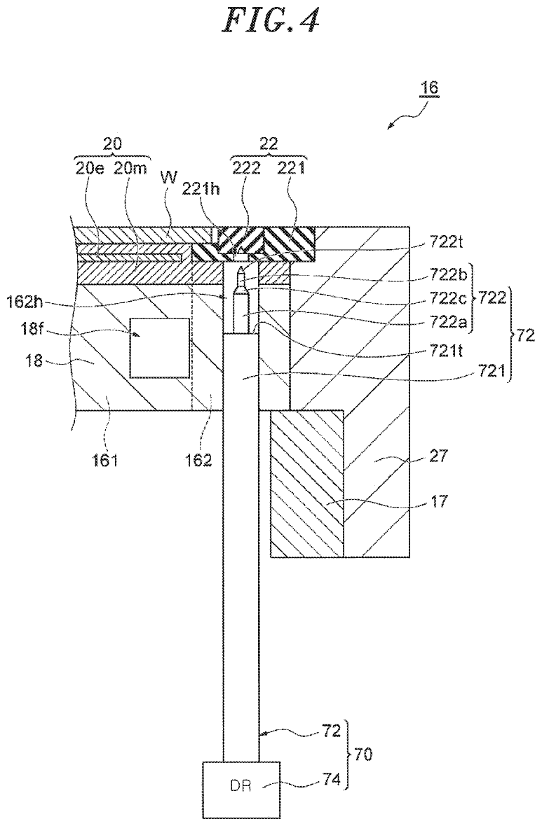

The plasma processing apparatus 1 further includes a substrate support 16. Referring now to FIGS. 3 and 4, in addition to FIG. 2, the substrate support 16 will now be described. FIG. 3 is a schematic diagram of the substrate support according to the exemplary embodiment. FIG. 4 is a partially enlarged view of the substrate support according to the exemplary embodiment. FIG. 4 is a partially cutaway view of the substrate support. The substrate support 16 supports the substrate W placed on the substrate support 16 in the chamber 10. The substrate W is substantially disk-shaped. The substrate support 16 is supported by a support 17. The support 17 extends upward from the bottom of the chamber 10. The support 17 is substantially cylindrical and is formed from an insulating material such as quartz.

The substrate support 16 includes a first portion 161 and a second portion 162. The first portion 161 supports the substrate W placed on the first portion 161. The first portion 161 is substantially circular in a plan view. The first portion 161 has the axis AX as its central axis. In one embodiment, the first portion 161 includes a base 18 and an electrostatic chuck (ESC) 20. In one embodiment, the first portion 161 may include a part of the base 18 and a part of the ESC 20. The base 18 and the ESC 20 are accommodated in the chamber 10. The base 18 is substantially disk-shaped and is formed from a conductive material such as aluminum. The base 18 serves as a lower electrode.

The base 18 has an internal channel 18f for carrying a heat-exchange medium. Examples of the heat-exchange medium include a liquid refrigerant and a refrigerant to be vaporized (e.g., chlorofluorocarbon) to cool the base 18. The channel 18f is connected to a supply unit (e.g., chiller unit) for supplying the heat-exchange medium. The supply unit is external to the chamber 10. The heat-exchange medium is supplied from the supply unit to the channel 18f, and then returns to the supply unit.

The ESC 20 is located on the base 18. The substrate W is placed on the first portion 161 and on the ESC 20 for processing in the chamber 10.

The second portion 162 extends radially outside the first portion 161 to surround the first portion 161. The second portion 162 is substantially annular in a plan view. An edge ring 22 is placed on the second portion 162. In one embodiment, the second portion 162 may include the base 18. The second portion 162 may further include the ESC 20. In one embodiment, the second portion 162 may include another part of the base 18 and another part of the ESC 20. The substrate W is placed on an area on the ESC 20 surrounded by the edge ring 22. The edge ring 22 will be described in detail later.

The second portion 162 has through-holes 162h extending vertically through the second portion 162. In one embodiment, the second portion 162 has multiple through-holes 162h. The through-holes 162h may be as many as lift pins 72 included in a lifter 70 (described later). Each through-hole 162h is aligned with the corresponding lift pin 72 on a straight line.

The ESC 20 includes a body 20m and an electrode 20e. The body 20m is formed from a dielectric such as aluminum oxide or aluminum nitride. The body 20m is substantially disk-shaped. The ESC 20 has the axis AX as its central axis. The electrode 20e is a film located in the body 20m. The electrode 20e is electrically coupled to a direct-current (DC) power supply via a switch. A voltage applied from the DC power supply to the electrode 20e generates an electrostatic attraction between the ESC 20 and the substrate W, thus causing the ESC 20 to attract and hold the substrate W.

The plasma processing apparatus 1 may further include a gas supply line 25. The gas supply line 25 supplies a heat-transfer gas (e.g., He gas) from a gas supply mechanism to a space between an upper surface of the ESC 20 and a back surface (lower surface) of the substrate W.

The plasma processing apparatus 1 may further include an outer peripheral member 27. The outer peripheral member 27 extends circumferentially and radially outward from the substrate support 16 to surround the substrate support 16. The outer peripheral member 27 may extend circumferentially and radially outward from the support 17 to surround the support 17. The outer peripheral member 27 may include one or more parts. The outer peripheral member 27 may be formed from an insulating material such as quartz.

The plasma processing apparatus 1 further includes an upper electrode 30. The upper electrode 30 is located above the substrate support 16. The upper electrode 30 closes a top opening of the chamber body 12 together with an insulating member 32. The upper electrode 30 is supported on an upper portion of the chamber body 12 with the member 32.

The upper electrode 30 includes a ceiling plate 34 and a support member 36. The ceiling plate 34 has its lower surface defining the internal space 10s. The ceiling plate 34 has multiple gas outlet holes 34a that are through-holes in the thickness direction (vertical direction). The ceiling plate 34 is formed from, but is not limited to, silicon. In some embodiments, the ceiling plate 34 may be an aluminum member coated with a plasma-resistant film. The film may be a ceramic film, such as an anodized film or a film formed from yttrium oxide.

The support member 36 supports the ceiling plate 34 in a detachable manner. The support member 36 is formed from a conductive material such as aluminum. The support member 36 has an internal gas-diffusion compartment 36a. Multiple gas holes 36b extend downward from the gas-diffusion compartment 36a. The gas holes 36b communicate with the respective gas outlet holes 34a. The support member 36 has a gas inlet 36c, which connects to the gas-diffusion compartment 36a. The gas inlet 36c also connects to a gas supply pipe 38.

The gas supply pipe 38 is connected to a set of gas sources (GS) 40 via a set of valves (VL) 41, a set of flow controllers (FC) 42, and a set of valves (VL) 43. The gas source set 40, the valve set 41, the flow controller set 42, and the valve set 43 form a gas supply unit GS. The gas source set 40 includes multiple gas sources. The valve sets 41 and 43 each include multiple valves (e.g., open-close valves). The flow controller set 42 includes multiple flow controllers. The flow controllers in the flow controller set 42 are mass flow controllers or pressure-based flow controllers. The gas sources in the gas source set 40 are connected to the gas supply pipe 38 via the respective valves in the valve set 41, via the respective flow controllers in the flow controller set 42, and via the respective valves in the valve set 43. The plasma processing apparatus 1 can supply gas from one or more gas sources selected from the multiple gas sources in the gas source set 40 to the internal space 10s at an individually regulated flow rate.

A baffle plate 48 is located between the substrate support 16 or the outer peripheral member 27 and a side wall of the chamber 10. The baffle plate 48 may include, for example, an aluminum member covered with ceramic such as yttrium oxide. The baffle plate 48 has many through-holes. An exhaust pipe 52 is connected to the bottom of the chamber 10 below the baffle plate 48. The exhaust pipe 52 is connected to an exhaust device (ED) 50. The exhaust device 50 includes a pressure controller such as an automatic pressure control valve and a vacuum pump such as a turbomolecular pump to reduce the pressure in the internal space 10s.

The plasma processing apparatus 1 further includes a radio-frequency (RF) power supply 61. The RF power supply 61 generates RF power (hereinafter referred to as the first RF power). The first RF power is used to generate plasma from a gas in the chamber 10. The first RF power has a first frequency ranging from 27 to 100 MHz. The RF power supply 61 is coupled to the upper electrode 30 via a matching circuit (MC) 61m. The matching circuit 61m matches the output impedance of the RF power supply 61 and the impedance of a load (the upper electrode 30). The RF power supply 61 may be coupled to the base 18 (in other words, the lower electrode), in place of the upper electrode 30, via the matching circuit 61m.

The plasma processing apparatus 1 further includes an RF power supply 62, which generates RF power (hereinafter referred to as the second RF power) for drawing ions in the plasma toward the substrate W. The second RF power has a second frequency lower than the first frequency. The second frequency ranges from, for example, 400 kHz to 13.56 MHz. The RF power supply 62 is coupled to the base 18 (in other words, the lower electrode) via a matching circuit (MC) 62m. The matching circuit 62m matches the output impedance of the RF power supply 62 and the impedance of a load (the base 18).

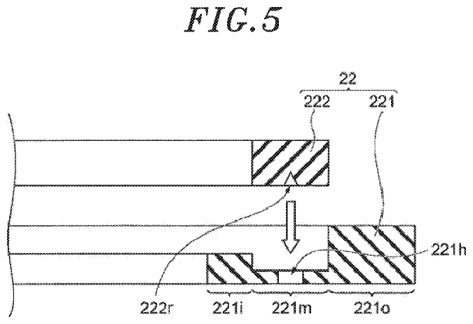

Referring now to FIG. 5 in addition to FIGS. 2 to 4, the edge ring 22 and the substrate support 16 will be described in detail. FIG. 5 is a partially enlarged cross-sectional view of the edge ring according to the exemplary embodiment. The edge ring 22 includes a first ring 221 and a second ring 222. FIG. 5 shows the first ring 221 and the second ring 222 that are separate from each other.

The first ring 221 and the second ring 222 are annular and each are formed from a material selected as appropriate for plasma processing performed in the plasma processing apparatus 1. The first ring 221 and the second ring 222 are formed from, for example, silicon or silicon carbide.

The first ring 221 is placed on the second portion 162 with its central axis aligned with the axis AX. In one embodiment, the first ring 221 may be placed on the second portion 162 and on the ESC 20. The first ring 221 may be placed on a component other than the ESC 20 in the second portion 162. In one embodiment, the first ring 221 includes an inner peripheral portion 221i, a receiving portion 221m, and an outer peripheral portion 221o as shown in FIG. 5. The inner peripheral portion 221i, the receiving portion 221m, and the outer peripheral portion 221o are annular and extend about the central axis of the first ring 221.

As shown in FIGS. 2 to 4, the inner peripheral portion 221i is nearer the central axis of the first ring 221 than the receiving portion 221m and the outer peripheral portion 221o, and extends circumferentially. The outer peripheral portion 221o extends outward from the inner peripheral portion 221i and the receiving portion 221m. The substrate W is placed on the ESC 20 with its edge extending on or above the inner peripheral portion 221i. The outer peripheral portion 221o is apart from the edge of the substrate W radially outward.

The receiving portion 221m extends circumferentially between the inner peripheral portion 221i and the outer peripheral portion 221o. The receiving portion 221m has a through-hole 221h extending vertically through the receiving portion 221m. In one embodiment, the receiving portion 221m has multiple through-holes 221h. The through-holes 221h may be as many as the lift pins 72 in the lifter 70.

Each through-hole 221h is sized to receive a second rod portion 722 (described later) of the corresponding lift pin 72, but is sized not to receive a first rod portion 721 (described later) of the corresponding lift pin 72. The through-hole 221h has a diameter smaller than the diameter of the first rod portion 721 and slightly larger than the diameter of the second rod portion 722 (or a first part 722a described later) when the first rod portion 721 and the second rod portion 722 are both cylindrical. The first ring 221 is placed on the second portion 162 to have the through-holes 221h aligned with the corresponding lift pins 72 on a straight line.

The receiving portion 221m has its upper surface vertically lower than the upper surfaces of the inner peripheral portion 221i and the outer peripheral portion 221o. The first ring 221 thus defines a recess on the receiving portion 221m. The second ring 222 is placed on the receiving portion 221m and fitted into the recess on the receiving portion 221m. The substrate W is placed on the ESC 20 with its end face facing the inner peripheral surface of the second ring 222.

The second ring 222 has a substantially flat lower surface. In one embodiment, the lower surface of the second ring 222 includes a tapered surface defining a recess 222r as shown in FIG. 5. In one embodiment, the lower surface of the second ring 222 has multiple recesses 222r. The tapered surfaces and the recesses 222r on the second ring 222 may be as many as the lift pins 72 in the lifter 70. Each recess 222r is sized to receive a distal end of the second rod portion 722 of the corresponding lift pin 72. The second ring 222 is placed on the receiving portion 221m to have the recesses 222r aligned with the corresponding lift pins 72 and the corresponding through-holes 221h on a straight line.

As shown in FIGS. 2 to 4, the substrate support 16 further includes the lifter 70. The lifter 70 includes the lift pins 72, and raises and lowers the first ring 221 and the second ring 222. In one embodiment, the lifter 70 includes multiple lift pins 72. The lifter 70 may include any number of lift pins 72 when the lifter 70 can support, and raise and lower the edge ring 22. The lifter 70 may include, for example, three lift pins 72.

Each lift pin 72 may be formed from an insulating material such as sapphire, alumina, quartz, silicon nitride, aluminum nitride, or a resin. The lift pin 72 includes the first rod portion 721 and the second rod portion 722. The first rod portion 721 extends vertically, and has a first upper end face 721t. The first upper end face 721t can come in contact with the lower surface of the first ring 221.

The second rod portion 722 extends vertically on the first rod portion 721. The second rod portion 722 is narrower than the first rod portion 721 to expose the first upper end face 721t. In one embodiment, the first rod portion 721 and the second rod portion 722 are cylindrical. In this embodiment, the first rod portion 721 has a larger diameter than the second rod portion 722. The second rod portion 722 is vertically movable through the through-hole 221h in the receiving portion 221m. The second rod portion 722 is vertically longer than the thickness of the receiving portion 221m.

The second rod portion 722 has a second upper end face 722t, which can come in contact with the second ring 222. In one embodiment, the distal end of the second rod portion 722 including the second upper end face 722t may be tapered to be fitted into the corresponding recess 222r.

In one embodiment, the second rod portion 722 may have the first part 722a and a second part 722b. The first part 722a is rod-like and extends upward from the first part 722a. The second part 722b is rod-like and extends upward above the first rod portion 721. The second part 722b has the second upper end face 722t. In this embodiment, the first part 722a is wider than the second part 722b.

In one embodiment, the first rod portion 721, the first part 722a, and the second part 722b may be cylindrical. In this embodiment, the first rod portion 721 has a larger diameter than the first part 722a, and the first part 722a has a larger diameter than the second part 722b.

In one embodiment, the second rod portion 722 may further include a third part 722c, which extends between the first part 722a and the second part 722b. In this embodiment, the third part 722c has a tapered surface.

In one embodiment, the lifter 70 includes one or more drives (DR) 74. The drives 74 raise and lower the multiple lift pins 72. Each drive 74 may include, for example, a motor.

In one embodiment, the plasma processing apparatus 1 may further include another gas supply unit (GSU) 76 as shown in FIG. 3. The gas supply unit 76 supplies a gas to the through-holes 162h to prevent discharge in the through-holes 162h. The gas supply unit 76 supplies an inert gas, such as a helium gas, to the through-holes 162h.

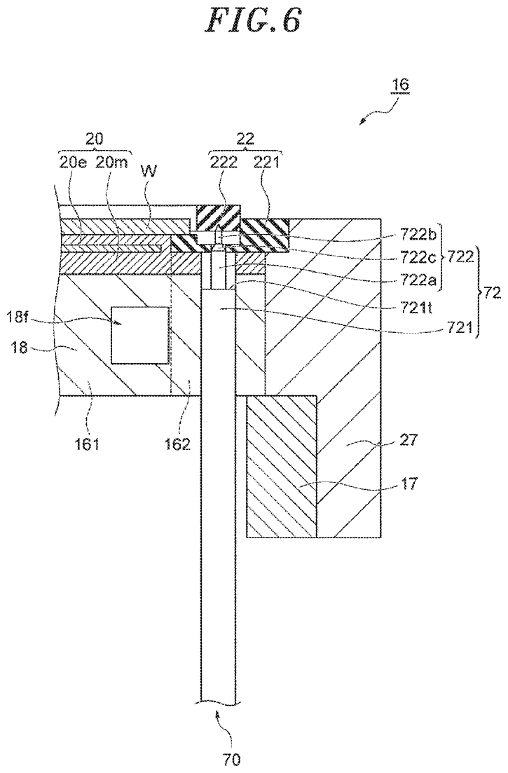

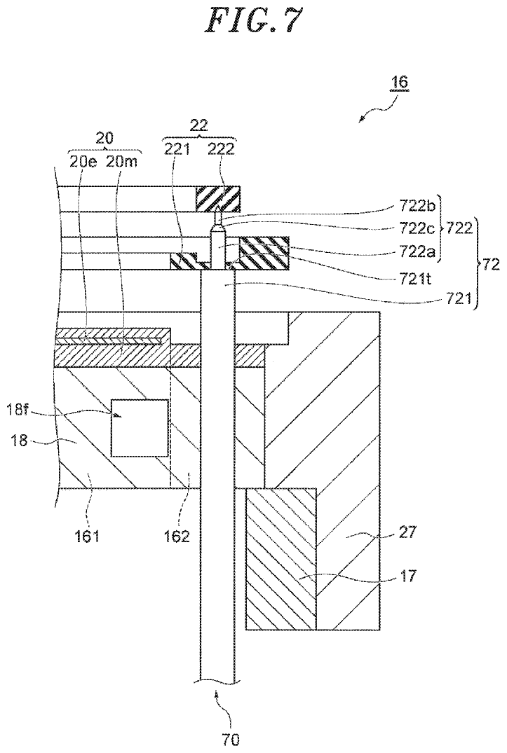

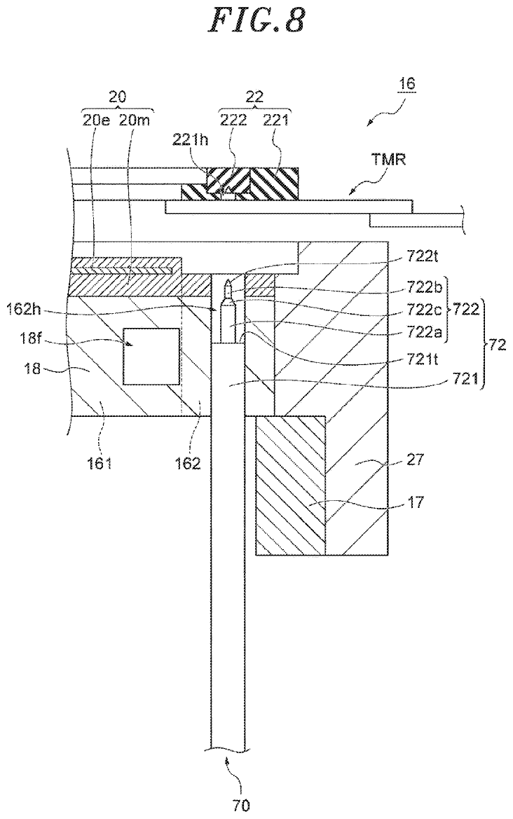

FIGS. 6 to 8 are partially enlarged views of the substrate support according to the exemplary embodiment. FIGS. 6 to 8 are partially cutaway views of the substrate support. In FIG. 6, the second ring 222 alone is located above the substrate support 16. In FIG. 7, both the first ring 221 and the second ring 222 are located above the substrate support 16. FIG. 8 shows the first ring 221 and the second ring 222 being transferred from the lift pin 72 in the lifter 70 to a transfer robot.

As shown in FIG. 6, the substrate support 16 allows the lifter 70 to raise and lower the second ring 222 alone with the lift pin 72 in contact with the second ring 222 at the second upper end face 722t, without being in contact with the first ring 221 at the first upper end face 721t. The lifter 70 can adjust the vertical position of the second ring 222 alone to adjust the vertical position of a boundary between plasma and sheath, thus allowing adjustment of the characteristics of the plasma processing performed on the edge of the substrate W.

In one embodiment, the second ring 222 is received in the recess on the receiving portion 221m. The structure according to this embodiment allows highly accurate positioning of the second ring 222 with respect to the first ring 221 and the substrate support 16.

In one embodiment, the second ring 222 is supported by the lift pins 72 with the distal ends of the second rod portions 722 of the lift pins 72 fitted in the corresponding recesses 222r on the second ring 222. The second ring 222 is thus less movable in the horizontal plane relative to the lift pins 72. The second ring 222 can be accurately positioned with respect to the lift pins 72, and thus can be accurately positioned on the first ring 221 and on the substrate support 16.

When the lift pins 72 supporting the second ring 222 are moved more upward, the first upper end faces 721t of the lift pins 72 come in contact with the first ring 221. More specifically, when the lift pins 72 are moved more upward, the first upper end faces 721t come in contact with the first ring 221, and the second upper end faces 722t come in contact with the second ring 222. In this state, the lifter 70 can raise and lower the first ring 221 and the second ring 222 together above the substrate support 16 as shown in FIG. 7. The substrate support 16 thus allows one or both the rings in the edge ring 22 to be raised or lowered alone or together with fewer lift pins 72.

As shown in FIG. 8, the transfer robot TMR is moved to a position below the edge ring 22, and the lift pins 72 are moved downward to transfer the edge ring 22 from the lift pins 72 to a handler of the transfer robot TMR. The transfer robot TMR then unloads the edge ring 22 from the chamber 10. At least one of the first ring 221 or the second ring 222 in the edge ring 22 is then replaced with an unused ring. The resultant edge ring 22 is then transferred into the chamber 10 by the transfer robot TMR and is placed onto the second portion 162 by the lifter 70.

In one embodiment, the second rod portion 722 of each lift pin 72 includes the first part 722a and the second part 722b as described above. The first part 722a extends upward from the first rod portion 721 and is wider than the second part 722b. In this embodiment, each lift pin 72 supports the first ring 221, with the first part 722a being partly received in the corresponding through-hole 221h as shown in FIG. 7. The first part 722a is relatively wider in the second rod portion 722. The first ring 221 is thus less movable in the horizontal plane relative to the lift pins 72. The first ring 221 can thus be positioned on the substrate support 16 with higher accuracy.

A method for replacing an edge ring in a substrate processing system according to exemplary embodiments will now be described. The control by the controller MC over the components of the substrate processing system will also be described, in addition to the method for replacing an edge ring according to the exemplary embodiments.

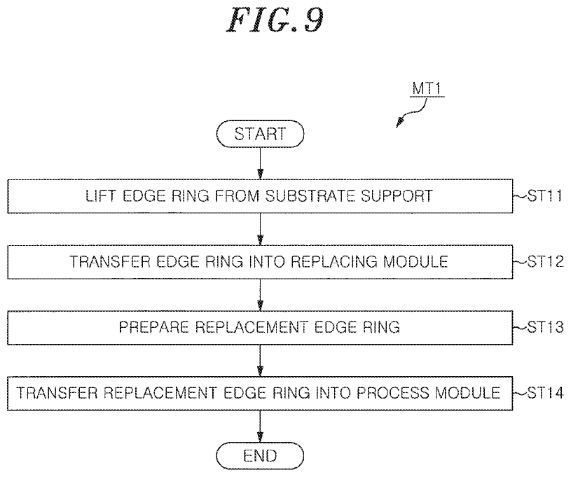

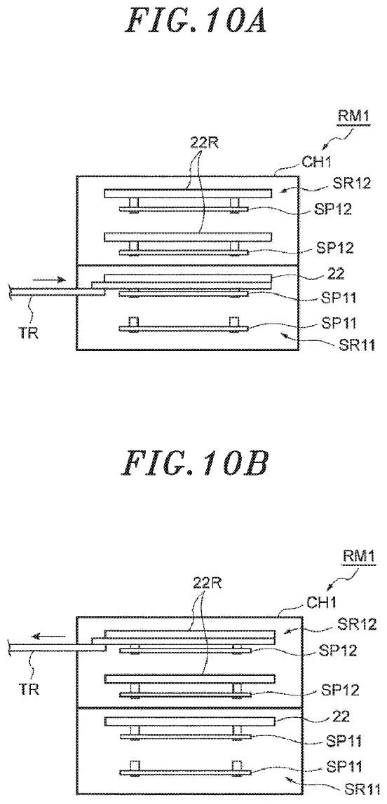

FIG. 9 is a flowchart of a method for replacing an edge ring according to an exemplary embodiment. A method MT1 in FIG. 9 may be used by the system SA including a replacing module RM1 shown in FIGS. 10A and 10B as the replacing module RM. FIGS. 10A and 10B are diagrams of the replacing module according to the exemplary embodiment. The process module PM3 in the system SA will be herein referred to as the process module PM, which is the plasma processing apparatus 1. One or more of the process modules PM1 to PM3 may be the process module PM.

As shown in FIGS. 10A and 10B, the replacing module RM1 includes a chamber CH1 defining an area SR11 and an area SR12. The area SR11 accommodates one or more support members SP11. In the illustrated example, the area SR11 accommodates two support members SP11. The two support members SP11 are vertically aligned with each other. Each support member SP11 can support the edge ring 22 transferred from the process module PM.

The area SR12 accommodates one or more support members SP12. In the illustrated example, the area SR12 accommodates two support members SP12. The two support members SP12 are vertically aligned with each other. Each support member SP12 can support an edge ring 22R, which is a replacement part to replace the edge ring 22 in the process module PM. The edge ring 22R may be an unused edge ring. The edge ring 22R includes a first ring 221 and a second ring 222.

As shown in FIG. 9, the method MT1 starts from step ST11. In step ST11, the edge ring 22 is lifted from the substrate support 16 by the lifter 70 in the chamber 10 in the process module PM as shown in FIG. 7. In step ST11, the controller MC controls the lifter 70 to lift the edge ring 22.

In subsequent step ST12, the edge ring 22 lifted by the lifter 70 is transferred from the process module PM into the replacing module RM1 by the transfer robot TR. The transfer robot TR may be the transfer robot TMR in the transfer module TM. In this case, the edge ring 22 may be transferred simply through the decompressed chamber in the transfer module TM. In step ST12, the controller MC controls the transfer robot TR to transfer the edge ring 22.

In step ST12, the vertical position of either the transfer robot TR or one of the support members SP11 is adjusted to avoid interference with each other. In step ST12, the vertical position of either a handler of the transfer robot TR or one of the support members SP11 is adjusted to transfer the edge ring 22 from the handler of the transfer robot TR to the support member SP11 as shown in FIG. 10A. For such vertical adjustment, either the transfer robot TR or the replacing module RM1 may include a position adjuster. In step ST12, the controller MC controls the position adjuster.

In step S12, the edge ring 22 is then transferred from the handler of the transfer robot TR to the support member SP11 as shown in FIG. 10A. In step ST12, the controller MC controls the transfer robot TR. After transferring the edge ring 22 to the support member SP11, the handler of the transfer robot TR retracts to avoid interference with the components of the replacing module RM1.

In subsequent step ST13, a replacement edge ring 22R is prepared. The replacement edge ring 22R is prestored as a replacement part in the area SR12 and is supported on one of the support members SP12.

In subsequent step ST14, the replacement edge ring 22R is transferred from the replacing module RM1 to the process module PM by the transfer robot TR. The transfer robot TR may be the transfer robot TMR in the transfer module TM. In this case, the replacement edge ring 22R may be transferred simply through the decompressed chamber in the transfer module TM. In step ST14, the controller MC controls the transfer robot TR to transfer the replacement edge ring 22R.

In step ST14, the vertical position of either the handler of the transfer robot TR or the support member SP12 is adjusted to avoid interference with each other. In step ST14, the vertical position of either the handler of the transfer robot TR or the support member SP12 is adjusted to transfer the replacement edge ring 22R from the support member SP12 to the handler of the transfer robot TR as shown in FIG. 10B. For such vertical adjustment, the position adjuster described above is used. In step ST14, the controller MC controls the position adjuster.

In step ST14, the replacement edge ring 22R is transferred from the handler of the transfer robot TMR to the lift pins 72 in the lifter 70 in the process module PM. The replacement edge ring 22R is then placed onto the substrate support 16. The controller MC controls the transfer robot TMR and the lifter 70 for this operation.

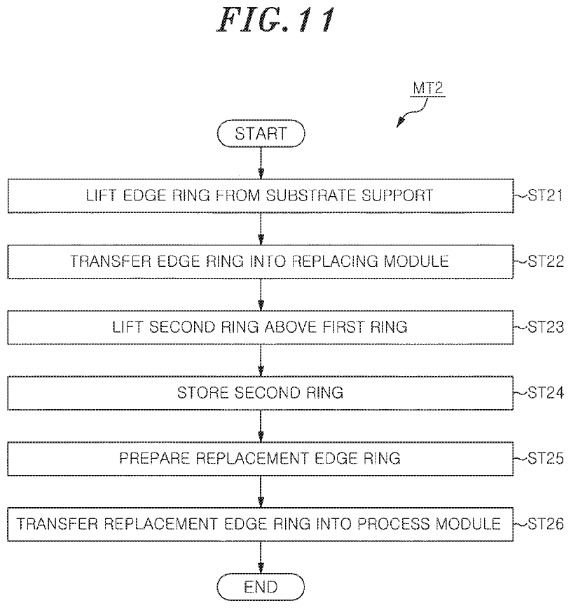

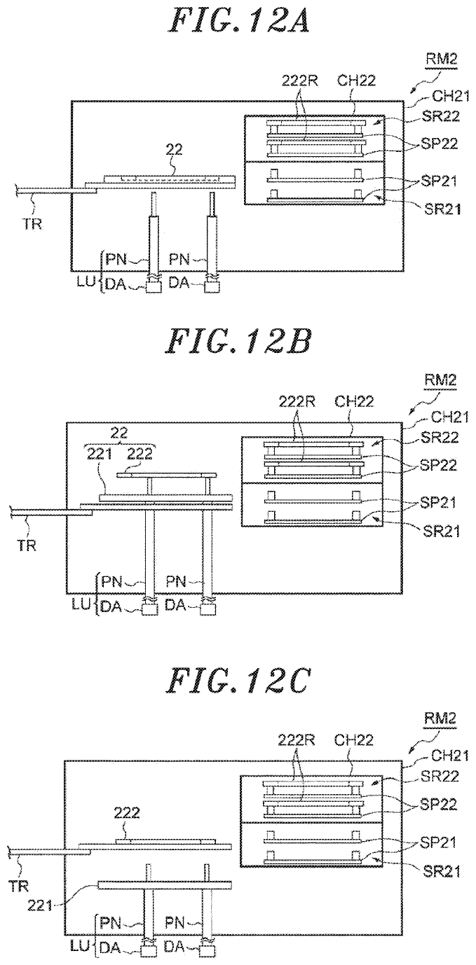

FIG. 11 is a flowchart of a method for replacing an edge ring according to another exemplary embodiment. FIGS. 12A to 14C are diagrams of a replacing module according to the other exemplary embodiment. A method MT2 shown in FIG. 11 may be used by the system SA including a replacing module RM2 shown in these figures as the replacing module RM. The process module PM3 in the system SA will be herein referred to as the process module PM, which is the plasma processing apparatus 1. One or more of the process modules PM1 to PM3 may be the process module PM.

The replacing module RM2 includes a chamber CH21 and a lifter LU. The lifter LU lifts the second ring 222 above the first ring 221 in the chamber CH21. The lifter LU may have the same structure as the lifter 70. In other words, the lifter LU may include one or more lift pins PN, which are similar to the lift pins 72, and one or more drives DA, which are similar to the drives 74.

The chamber CH21 defines an area SR21 serving as a first storage area and an area SR22 serving as a second storage area. In one embodiment, the chamber CH21 accommodates another chamber CH22. The chamber CH22 may define the area SR21 and the area SR22 inside.

The area SR21 accommodates one or more support members SP21. In the illustrated examples, the area SR21 accommodates two support members SP21. The two support members SP21 are vertically aligned with each other. Each support member SP21 can support the second ring 222 in the edge ring 22 transferred from the process module PM.

The area SR22 accommodates one or more support members SP22. In the illustrated examples, the area SR22 accommodates two support members SP22. Each support member SP22 can support a ring 222R, which is a replacement part to replace the second ring 222 in the edge ring 22 located in the process module PM. The ring 222R may be an unused second ring 222.

As shown in FIG. 11, the method MT2 starts from step ST21. The processing in step ST21 is similar to the processing in step ST11. In step ST21, the edge ring 22 is lifted from the substrate support 16 by the lifter 70 in the chamber 10 in the process module PM. In step ST21, the controller MC controls the lifter 70 to lift the edge ring 22.

In subsequent step ST22, the edge ring 22 lifted by the lifter 70 is transferred from the process module PM into the replacing module RM2 by the transfer robot TR as shown in FIG. 12A. The transfer robot TR may be the transfer robot TMR in the transfer module TM. In this case, the edge ring 22 may be transferred simply through the decompressed chamber in the transfer module TM. In step ST22, the controller MC controls the transfer robot TR to transfer the edge ring 22.

In subsequent step ST23, the lifter LU lifts the second ring 222 above the first ring 221 as shown in FIG. 12B. In step ST23, the controller MC controls the lifter LU to lift the second ring 222 above the first ring 221. After step ST23, the handler of the transfer robot TR retracts to avoid interference with the first ring 221.

In subsequent step ST24, the second ring 222 is stored into the area SR21. In step ST24, the second ring 222 is transferred from the lift pins PN to the handler of the transfer robot TR as shown in FIG. 12C. More specifically, the lift pins PN are lowered to allow the handler of the transfer robot TR to advance between the first ring 221 and the second ring 222. The handler of the transfer robot TR then advances between the first ring 221 and the second ring 222. The lift pins PN are then lowered further to transfer the second ring 222 from the lift pins PN to the handler of the transfer robot TR. In step ST24, the controller MC controls the transfer robot TR and the lifter LU to transfer the second ring 222 from the lift pins PN to the handler of the transfer robot TR.

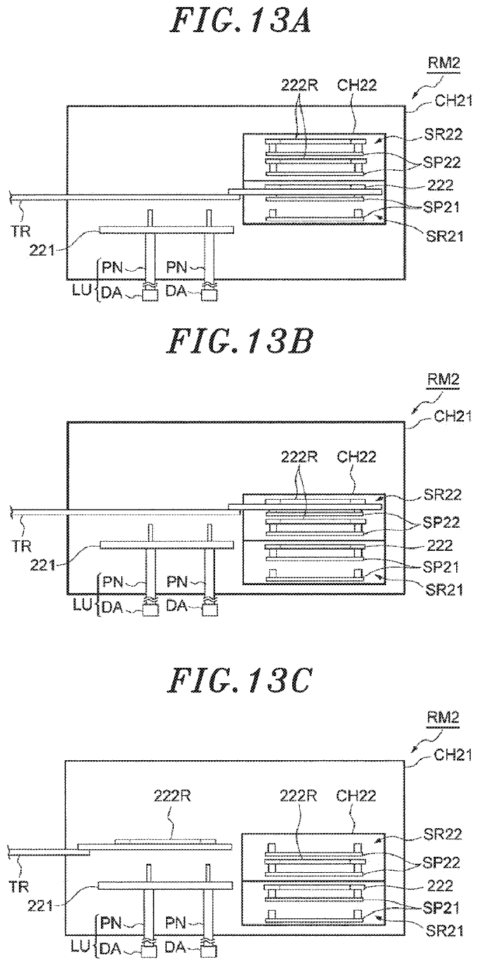

In step ST24, the vertical position of either the handler of the transfer robot TR or one of the support members SP21 is then adjusted to avoid interference with each other. In step ST24, the vertical position of either the handler of the transfer robot TR or the support member SP21 is adjusted to transfer the second ring 222 from the handler of the transfer robot TR to the support member SP21 as shown in FIG. 13A. For such vertical adjustment, either the transfer robot TR or the replacing module RM2 may include a position adjuster. In step ST24, the controller MC controls the position adjuster.

In step S24, the second ring 222 is then transferred from the handler of the transfer robot TR to the support member SP21 as shown in FIG. 13A. In step ST24, the controller MC controls the transfer robot TR. After transferring the second ring 222 to the support member SP21, the handler of the transfer robot TR retracts to avoid interference with the components of the replacing module RM2.

In subsequent step ST25, a replacement edge ring 22R is prepared. In step ST25, a ring 222R is transferred from one of the support members SP22 to the handler of the transfer robot TR first. More specifically, the vertical position of either the handler of the transfer robot TR or the support member SP22 is adjusted by the position adjuster described above to avoid interference with each other. The handler of the transfer robot TR then advances into the area SR22 to receive the ring 222R from the support member SP22 as shown in FIG. 13B. The handler of the transfer robot TR receiving the ring 222R then retracts from the area SR22 as shown in FIG. 13C.

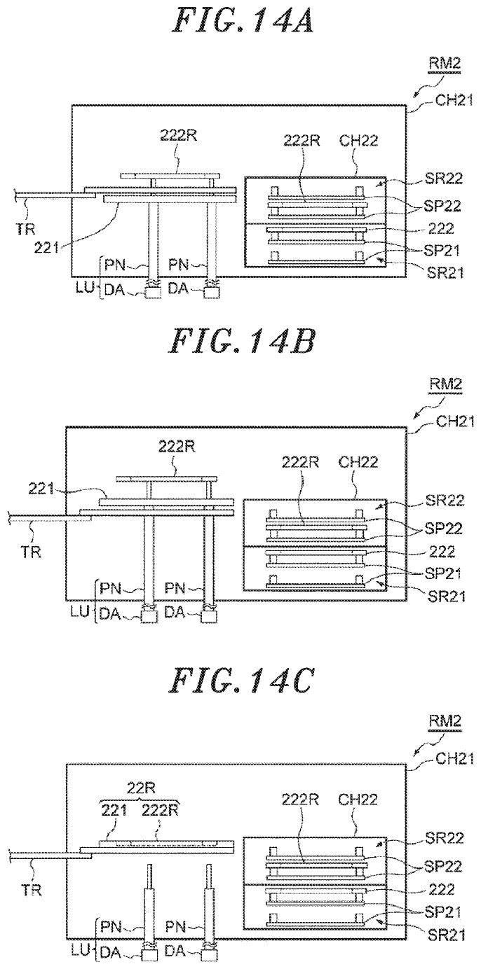

In step ST25, the lift pins PN are raised. The ring 222R is thus transferred from the handler of the transfer robot TR to the lift pins PN as shown in FIG. 14A. The handler of the transfer robot TR then retracts to avoid interference with the first ring 221. The lift pins PN are raised further to allow the handler of the transfer robot TR to advance below the first ring 221. The handler of the transfer robot TR then advances into an area below the first ring 221 as shown in FIG. 14B. The lift pins PN are then lowered to transfer the first ring 221 and the ring 222R from the lift pins PN to the handler of the transfer robot TR. The edge ring 22R including the first ring 221 and the ring 222R is thus prepared as shown in FIG. 14C. In step ST25, the controller MC controls the transfer robot TR, the lifter LU, and the position adjuster described above to prepare the replacement edge ring 22R.

In subsequent step ST26, the replacement edge ring 22R is transferred from the replacing module RM2 into the process module PM by the transfer robot TR. The transfer robot TR may be the transfer robot TMR in the transfer module TM. In this case, the replacement edge ring 22R may be transferred simply through the decompressed chamber in the transfer module TM. In step ST26, the controller MC controls the transfer robot TR to transfer the replacement edge ring 22R.

In step ST26, the replacement edge ring 22R is transferred from the handler of the transfer robot TMR to the lift pins PN in the lifter 70 in the process module PM. The replacement edge ring 22R is then placed onto the substrate support 16. The controller MC controls the transfer robot TMR and the lifter 70 for this operation.

The second ring 222 may not be stored into the area SR21 in step ST24 of the method MT2. In step ST24, the second ring 222 may be transferred into either the loadlock module LL1 or LL2 by the transfer robot TR. The second ring 222 may be then transferred from the loadlock module to a container located at one of the load ports LP1 to LP4 and stored into the container by the transfer robot LMR. In this case, in step ST24, the controller MC controls the transfer robot TR and the transfer robot LMR to store the second ring 222 into the container located at the load port. In this case, the replacing module RM2 may eliminate the area SR21.

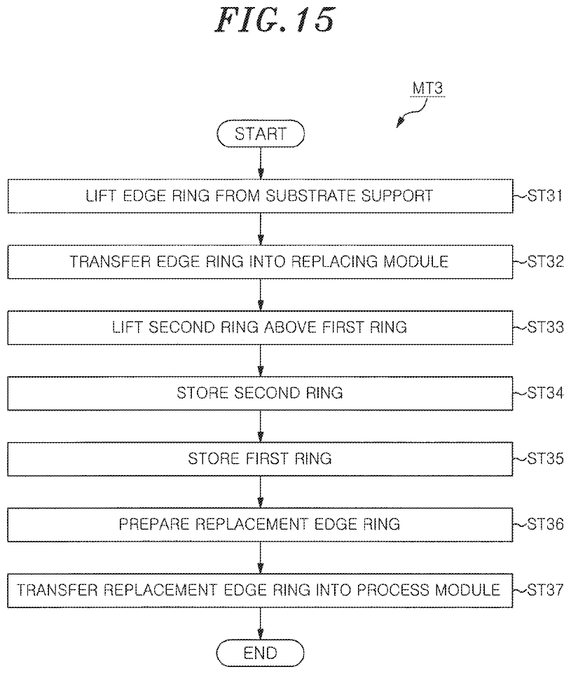

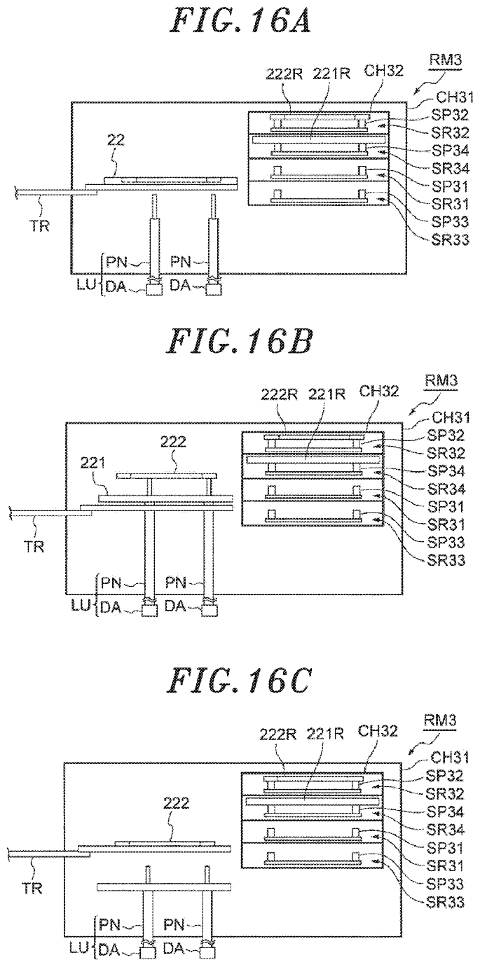

FIG. 15 is a flowchart of a method for replacing an edge ring according to still another exemplary embodiment. FIGS. 16A to 20B show the method for replacing an edge ring according to the other exemplary embodiment. A method MT3 shown in FIG. 15 may be used by the system SA including a replacing module RM3 shown in these figures as the replacing module RM. The process module PM3 in the system SA will be herein referred to as the process module PM, which is the plasma processing apparatus 1. One or more of the process modules PM1 to PM3 may be the process module PM.

The replacing module RM3 includes a chamber CH31 and a lifter LU. The lifter LU lifts the second ring 222 above the first ring 221 in the chamber CH31. The lifter LU may have the same structure as the lifter 70. In other words, the lifter LU may include one or more lift pins PN, which are similar to the lift pins 72, and one or more drives DA, which are similar to the drives 74.

The chamber CH31 defines an area SR31 serving as a first storage area and an area SR32 serving as a second storage area. In one embodiment, the chamber CH31 accommodates another chamber CH32. The chamber CH32 may define the area SR31 and the area SR32 inside.

The area SR31 accommodates one or more support members SP31. In the illustrated examples, the area SR31 accommodates one support member SP31. The support member SP31 can support the second ring 222 in the edge ring 22 transferred from the process module PM. The area SR32 accommodates one or more support members SP32. In the illustrated examples, the area SR32 accommodates one support member SP32. The support member SP32 can support a ring 222R, which is a replacement part to replace the second ring 222 in the edge ring 22 located in the process module PM. The ring 222R may be an unused second ring 222.

The chamber CH31 defines an area SR33 serving as a third storage area and an area SR34 serving as a fourth storage area. The chamber CH32 may define the area SR33 and the area SR34 inside.

The area SR33 accommodates one or more support members SP33. In the illustrated examples, the area SR33 accommodates one support member SP33. The support member SP33 can support the first ring 221 in the edge ring 22 transferred from the process module PM.

The area SR34 accommodates one or more support members SP34. In the illustrated examples, the area SR34 accommodates one support member SP34. The support member SP34 can support a ring 221R, which is a replacement part to replace the first ring 221 in the edge ring 22 located in the process module PM. The ring 221R may be an unused first ring 221.

As shown in FIG. 15, the method MT3 starts from step ST31. The processing in step ST31 is similar to the processing in step ST11. In step ST31, the edge ring 22 is lifted from the substrate support 16 by the lifter 70 in the chamber 10 in the process module PM. In step ST31, the controller MC controls the lifter 70 to lift the edge ring 22.

In subsequent step ST32, the edge ring 22 lifted by the lifter 70 is transferred from the process module PM into the replacing module RM3 by the transfer robot TR as shown in FIG. 16A. The transfer robot TR may be the transfer robot TMR in the transfer module TM. In this case, the edge ring 22 may be transferred simply through the decompressed chamber in the transfer module TM. In step ST32, the controller MC controls the transfer robot TR to transfer the edge ring 22.

In subsequent step ST33, the lifter LU lifts the second ring 222 above the first ring 221 as shown in FIG. 16B. In step ST33, the controller MC controls the lifter LU to lift the second ring 222 above the first ring 221. After step ST33, the handler of the transfer robot TR retracts to avoid interference with the first ring 221.

In subsequent step ST34, the second ring 222 is stored into the area SR31. In step ST34, the second ring 222 is transferred from the lift pins PN to the handler of the transfer robot TR as shown in FIG. 16C. More specifically, the lift pins PN are lowered to allow the handler of the transfer robot TR to advance between the first ring 221 and the second ring 222. The handler of the transfer robot TR then advances between the first ring 221 and the second ring 222. The lift pins PN are then lowered further to transfer the second ring 222 from the lift pins PN to the handler of the transfer robot TR. In step ST34, the controller MC controls the transfer robot TR and the lifter LU to transfer the second ring 222 from the lift pins PN to the handler of the transfer robot TR.

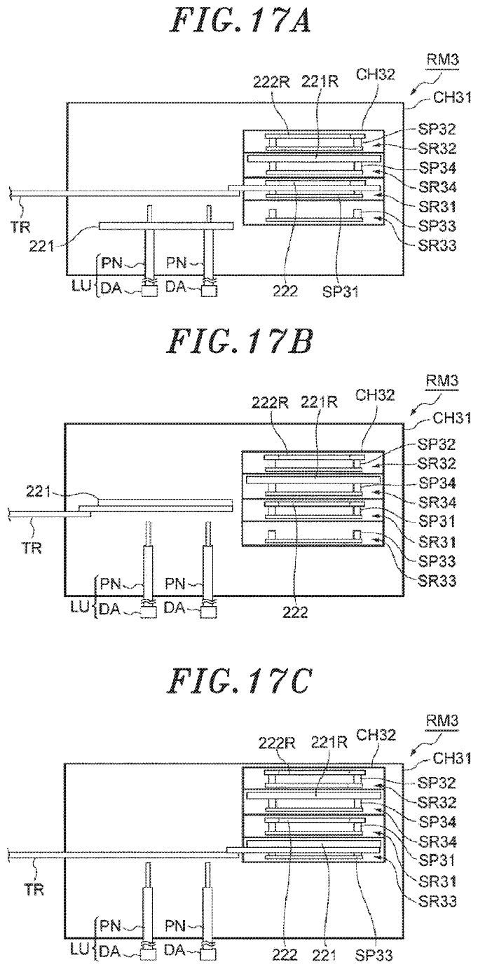

In step ST34, the vertical position of either the handler of the transfer robot TR or the support member SP31 is then adjusted to avoid interference with each other. In step ST34, the vertical position of either the handler of the transfer robot TR or the support member SP31 is adjusted to transfer the second ring 222 from the handler of the transfer robot TR to the support member SP31 as shown in FIG. 17A. For such vertical adjustment, either the transfer robot TR or the replacing module RM3 may include a position adjuster. In step ST34, the controller MC controls the position adjuster.

In step ST34, the second ring 222 is then transferred from the handler of the transfer robot TR to the support member SP31 as shown in FIG. 17A. In step ST34, the controller MC controls the transfer robot TR. After transferring the second ring 222 to the support member SP31, the handler of the transfer robot TR retracts to avoid interference with the components of the replacing module RM3.

In subsequent step ST35, the first ring 221 is stored into the area SR33. In step ST35, the first ring 221 is transferred from the lift pins PN to the handler of the transfer robot TR as shown in FIG. 17B. More specifically, the lift pins PN are raised. The handler of the transfer robot TR then advances into an area below the first ring 221. The lift pins PN are then lowered to transfer the first ring 221 from the lift pins PN to the handler of the transfer robot TR. In step ST35, the controller MC controls the transfer robot TR and the lifter LU to transfer the first ring 221 from the lift pins PN to the transfer robot TR.

In step ST35, the vertical position of either the handler of the transfer robot TR or the support member SP33 is then adjusted to avoid interference with each other. In step ST35, the vertical position of either the handler of the transfer robot TR or the support member SP33 is adjusted to transfer the first ring 221 from the handler of the transfer robot TR to the support member SP33 as shown in FIG. 17C. For such vertical adjustment, the controller MC controls the position adjuster described above.

In step ST35, the first ring 221 is then transferred from the handler of the transfer robot TR to the support member SP33 as shown in FIG. 17C. In step ST35, the controller MC controls the transfer robot TR. After transferring the first ring 221 to the support member SP33, the handler of the transfer robot TR retracts to avoid interference with the components of the replacing module RM3.

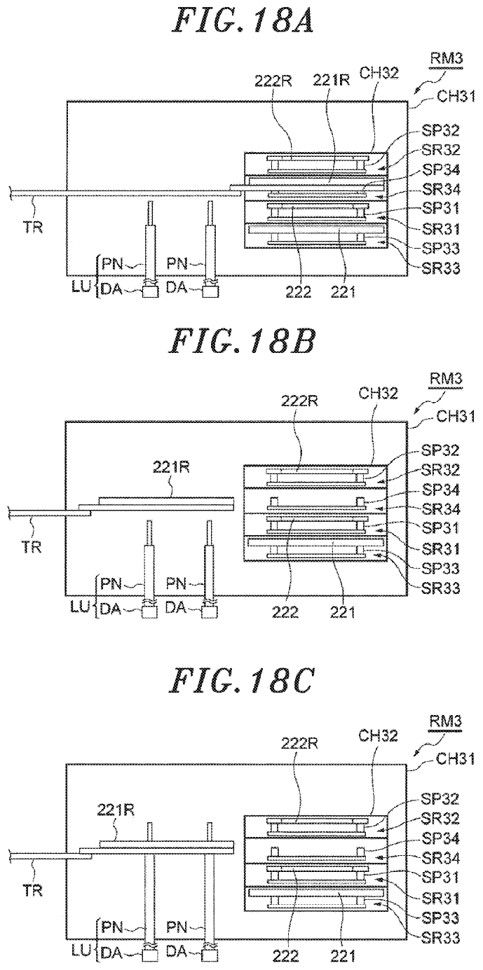

In subsequent step ST36, a replacement edge ring 22R is prepared. In step ST36, a ring 221R is transferred from the support member SP34 to the handler of the transfer robot TR first. More specifically, the vertical position of either the handler of the transfer robot TR or the support member SP34 is adjusted by the position adjuster to avoid interference with each other. The handler of the transfer robot TR then advances into the area SR34 to receive the ring 221R from the support member SP34 as shown in FIG. 18A. The handler of the transfer robot TR receiving the ring 221R then retracts from the area SR34 as shown in FIG. 18B.

In step ST36, the lift pins PN are raised. The ring 221R is thus transferred from the handler of the transfer robot TR to the lift pins PN as shown in FIG. 18C. The handler of the transfer robot TR then retracts to avoid interference with the ring 221R. The lift pins PN are then lowered.

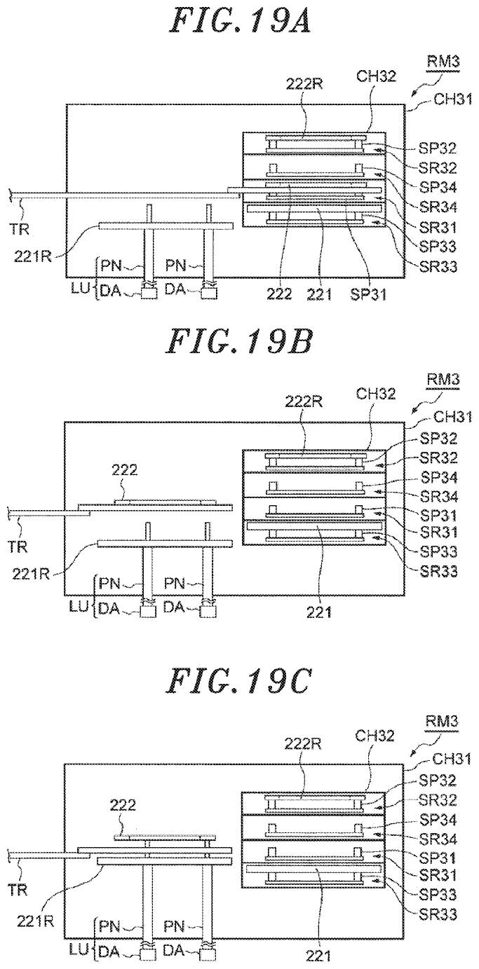

In step ST36, the second ring 222 is then transferred from the support member SP31 to the handler of the transfer robot TR. More specifically, the vertical position of either the handler of the transfer robot TR or the support member SP31 is adjusted by the position adjuster to avoid interference with each other. The handler of the transfer robot TR then advances into the area SR31 to receive the second ring 222 from the support member SP31 as shown in FIG. 19A. The handler of the transfer robot TR receiving the second ring 222 then retracts from the area SR31 as shown in FIG. 19B.

In step ST36, the lift pins PN in the lifter LU are raised. The second ring 222 is thus transferred from the handler of the transfer robot TR to the lift pins PN as shown in FIG. 19C. The handler of the transfer robot TR then retracts to avoid interference with the ring 221R.

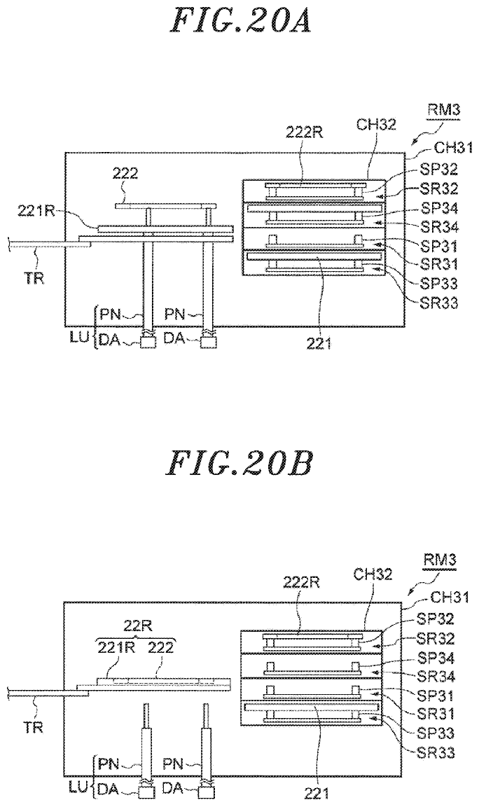

In step ST36, the ring 221R and the second ring 222 are then transferred from the lift pins PN to the handler of the transfer robot TR. More specifically, the lift pins PN are raised. The handler of the transfer robot TR then advances into an area below the ring 221R as shown in FIG. 20A. The lift pins PN are then lowered to transfer the ring 221R and the second ring 222 from the lift pins PN to the handler of the transfer robot TR. The replacement edge ring 22R including the ring 221R and the second ring 222 is thus prepared as shown in FIG. 20B. In step ST36, the controller MC controls the transfer robot TR, the lifter LU, and the position adjuster described above to prepare the replacement edge ring 22R.

In subsequent step ST37, the replacement edge ring 22R is transferred from the replacing module RM3 into the process module PM by the transfer robot TR. The transfer robot TR may be the transfer robot TMR in the transfer module TM. In this case, the replacement edge ring 22R may be transferred simply through the decompressed chamber in the transfer module TM. In step ST37, the controller MC controls the transfer robot TR to transfer the replacement edge ring 22R.

In step ST37, the replacement edge ring 22R is transferred from the transfer robot TMR to the lift pins 72 in the lifter 70 in the process module PM. The replacement edge ring 22R is then placed onto the substrate support 16. The controller MC controls the transfer robot TMR and the lifter 70 for this operation.

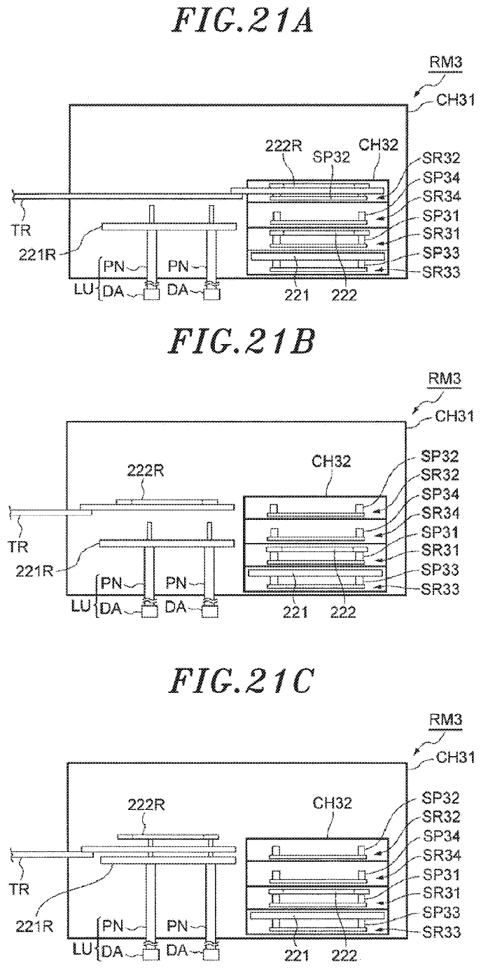

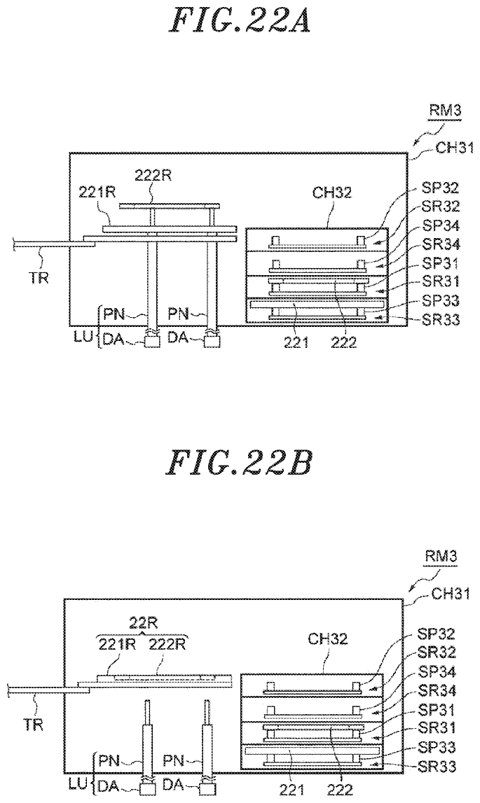

FIG. 15 will now be referred to with FIGS. 21A to 22B, which are diagrams of a replacing module according to still another exemplary embodiment. In step ST36 of the method MT3, a replacement edge ring 22R including a ring 221R and a ring 222R may be prepared.

More specifically, in step ST36, after transferring the ring 221R to the lift pins PN, the handler of the transfer robot TR retracts to avoid interference with the ring 221R. The lift pins PN are then lowered.

In step ST36, the ring 222R is then transferred from the support member SP32 to the handler of the transfer robot TR. More specifically, the vertical position of either the handler of the transfer robot TR or the support member SP32 is adjusted by the position adjuster to avoid interference with each other. The handler of the transfer robot TR then advances into the area SR32 to receive the ring 222R from the support member SP32 as shown in FIG. 21A. The handler of the transfer robot TR receiving the ring 222R then retracts from the area SR32 as shown in FIG. 21B.

In step ST36, the lift pins PN are raised. The ring 222R is thus transferred from the handler of the transfer robot TR to the lift pins PN as shown in FIG. 21C. The handler of the transfer robot TR then retracts to avoid interference with the ring 221R.

In step ST36, the ring 221R and the ring 222R are then transferred from the lift pins PN to the handler of the transfer robot TR. More specifically, the lift pins PN are raised. The handler of the transfer robot TR then advances into an area below the ring 221R as shown in FIG. 22A. The lift pins PN are then lowered to transfer the ring 221R and the ring 222R from the lift pins PN to the handler of the transfer robot TR. The replacement edge ring 22R including the ring 221R and the ring 222R is thus prepared as shown in FIG. 22B. In step ST36, the controller MC controls the transfer robot TR, the lifter LU, and the position adjuster described above to prepare the replacement edge ring 22R.

When the second ring 222 is replaced with the ring 222R with the method MT3, the second ring 222 may not be stored into the area SR31 in step ST34. In step ST34, the second ring 222 may be transferred into either the loadlock module LL1 or LL2 by the transfer robot TR. The second ring 222 may be then transferred from the loadlock module to a container located at one of the load ports LP1 to LP4 and stored into the container by the transfer robot LMR. In this case, in step ST24, the controller MC controls the transfer robot TR and the transfer robot LMR to store the second ring 222 into the container located at the load port. In this case, the replacing module RM3 may eliminate the area SR31.

The first ring 221 may not be stored into the area SR33 in step ST35 of the method MT3. In step ST35, the first ring 221 may be transferred into either the loadlock module LL1 or LL2 by the transfer robot TR. The first ring 221 may be then transferred from the loadlock module to a container located at one of the load ports LP1 to LP4 and stored into the container by the transfer robot LMR. In this case, in step ST35, the controller MC controls the transfer robot TR and the transfer robot LMR to store the first ring 221 into the container located at the load port. In this case, the replacing module RM3 may eliminate the area SR33.

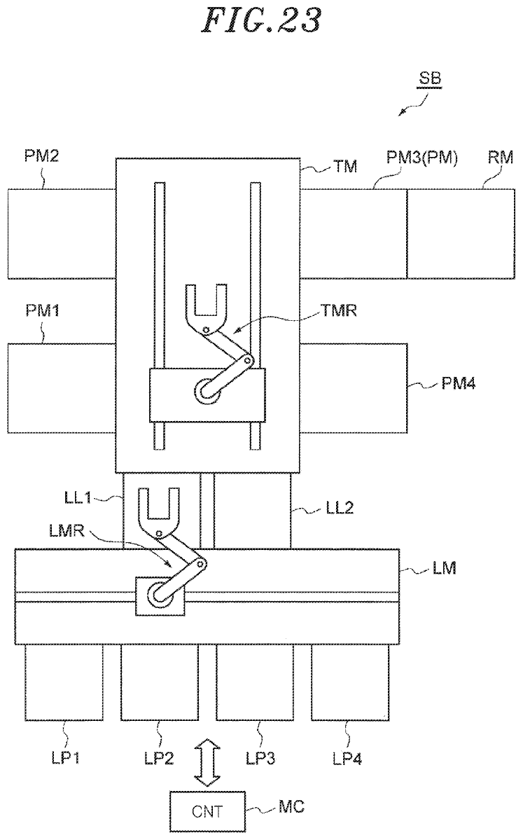

FIG. 23 is a diagram of a substrate processing system according to another exemplary embodiment. The substrate processing system shown in FIG. 23 (hereinafter referred to as the system SB) includes a process module PM4, in addition to the process modules PM1 to PM3. The process module PM4 is a substrate processing apparatus dedicated to intended substrate processing. The process module PM4 is connected to the transfer module TM. The process module PM4 may be the plasma processing apparatus 1. In system SB, the replacing module RM is directly connected to the process module PM. The replacing module RM is connected to the transfer module TM via the process module PM. In the illustrated example, the process module PM3 serves as the process module PM. However, one or more of the process modules PM1 to PM3 may serve as the process module PM. Other components of the system SB may be identical to those in the system SA.

The method MT1 may be used by the system SB including the replacing module RM1, which serves as the replacing module RM. The method MT2 may also be used by the system SB including the replacing module RM2, which serves as the replacing module RM. The method MT3 may also be used by the system SB including the replacing module RM3, which serves as the replacing module RM. With the methods MT1 to MT3, the transfer robot TMR may be used as the transfer robot TR. In some embodiments, with the methods MT1 to MT3, another transfer robot included in the process module PM or in the replacing module RM may be used as the transfer robot TR.

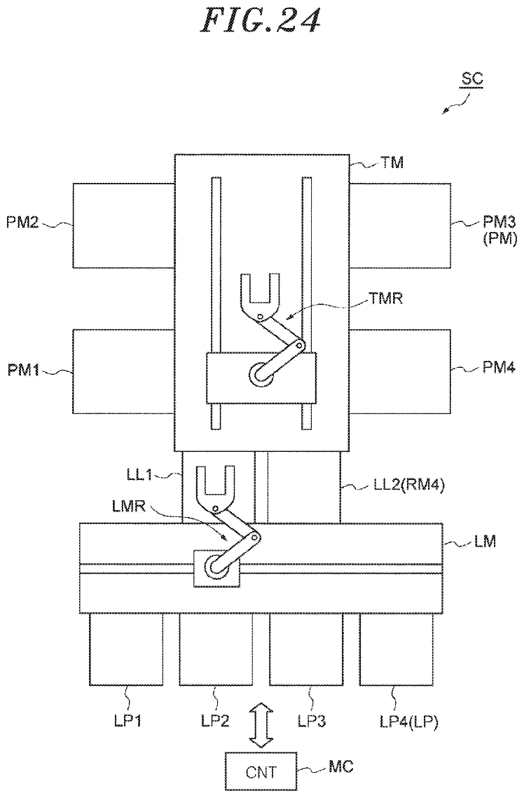

FIG. 24 is a diagram of a substrate processing system according to still another exemplary embodiment. A substrate processing system shown in FIG. 24 (hereinafter referred to as the system SC) includes the loadlock module as a replacing module RM4. In the illustrated example, the loadlock module LL2 serves as the replacing module RM4. The loadlock module LL1 may also serve as the replacing module RM4. Other components of the system SC may be identical to those in the system SB.

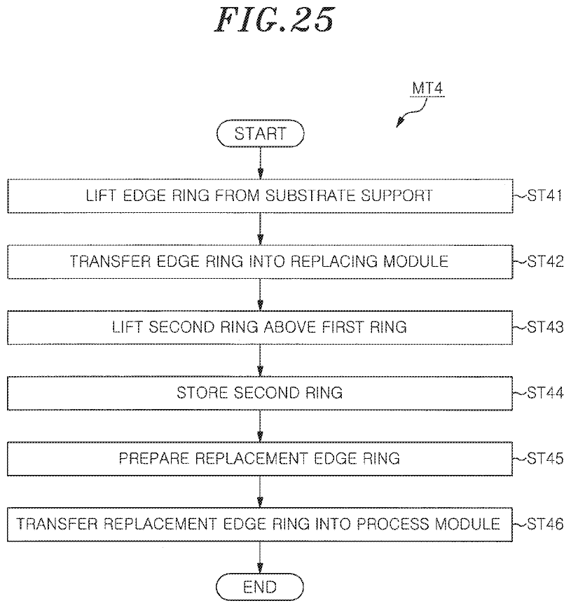

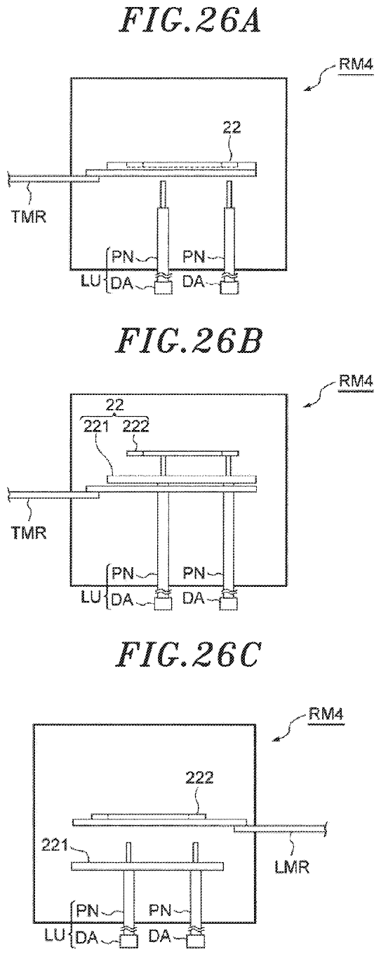

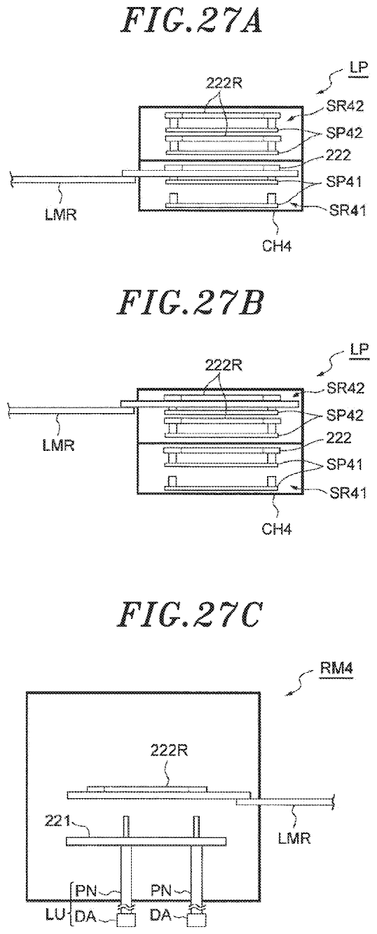

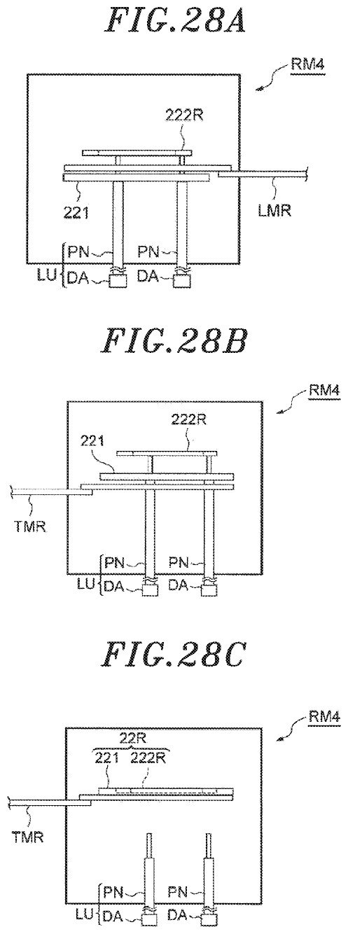

FIG. 25 is a flowchart of a method for replacing an edge ring according to still another exemplary embodiment. A method MT4 shown in FIG. 25 may be used by the system SC. FIG. 25 will now be referred to with FIGS. 26A to 28C. FIGS. 26A to 26C are diagrams of a replacing module according to the other exemplary embodiment. FIGS. 27A and 27B are diagrams showing first and second storage areas located at a load port, and FIG. 27C is a diagram of the replacing module according to the other exemplary embodiment. FIGS. 28A to 28C are diagrams of the replacing module according to the other exemplary embodiment.

As shown in, for example, FIG. 26A, the replacing module RM4, or the loadlock module, includes the lifter LU. The lifter LU lifts the second ring 222 above the first ring 221 in the chamber in the loadlock module. The lifter LU may have the same structure as the lifter 70. In other words, the lifter LU may include one or more lift pins PN, which are similar to the lift pins 72, and one or more drives DA, which are similar to the drives 74.

As shown in FIG. 27A, in the system SC, one load port LP of the load ports LP1 to LP4 defines an area SR41 serving as a first storage area and an area SR42 serving as a second storage area. In one embodiment, a chamber CH4 defines the area SR41 and the area SR42 inside.

The area SR41 accommodates one or more support members SP41. In the illustrated examples, the area SR41 accommodates two support members SP41. The two support members SP41 are vertically aligned with each other. Each support member SP41 can support the second ring 222 in the edge ring 22 transferred from the process module PM. In the example shown in FIG. 24, the process module PM3 serves as the process module PM. However, one or more of the process modules PM1 to PM3 may serve as the process module PM.

As shown in, for example, FIG. 27A, the area SR42 accommodates one or more support members SP42. In the illustrated examples, the area SR42 accommodates two support members SP42. Each support member SP42 can support a ring 222R, which is a replacement part to replace the second ring 222 in the edge ring 22 located in the process module PM. The ring 222R may be an unused second ring 222.

As shown in FIG. 25, the method MT4 starts from step ST41. The processing in step ST41 is similar to the processing in step ST11. In step ST41, the edge ring 22 is lifted from the substrate support 16 by the lifter 70 in the chamber 10 in the process module PM. In step ST41, the controller MC controls the lifter 70 to lift the edge ring 22.

In subsequent step ST42, the edge ring 22 lifted by the lifter 70 is transferred from the process module PM into the replacing module RM4 (in other words, the loadlock module) by the transfer robot TMR as shown in FIG. 26A. In step ST42, the controller MC controls the transfer robot TMR to transfer the edge ring 22.

In subsequent step ST43, the lifter LU lifts the second ring 222 above the first ring 221 as shown in FIG. 26B. In step ST43, the controller MC controls the lifter LU to lift the second ring 222 above the first ring 221. After step ST43, the handler of the transfer robot TMR retracts.

In subsequent step ST44, the second ring 222 is stored into the area SR41. In step ST44, the second ring 222 is transferred from the lift pins PN in the lifter LU to the handler of the transfer robot LMR as shown in FIG. 26C. More specifically, the handler of the transfer robot LMR advances between the first ring 221 and the second ring 222. The lift pins PN are then lowered to transfer the second ring 222 from the lift pins PN to the handler of the transfer robot LMR. In step ST44, the controller MC controls the transfer robot LMR and the lifter LU to transfer the second ring 222 from the lift pins PN in the lifter LU to the handler of the transfer robot LMR.

In step ST44, the second ring 222 is then transferred into the area SR41 by the transfer robot LMR as shown in FIG. 27A. The second ring 222 is then transferred from the handler of the transfer robot LMR to one of the support members SP41. In step ST44, the controller MC controls the transfer robot LMR to transfer the second ring 222 from the handler of the transfer robot LMR to the support member SP41.

In subsequent step ST45, a replacement edge ring 22R is prepared. In step ST45, the ring 222R stored in the area SR42 is transferred from one of the support members SP42 to the handler of the transfer robot LMR as shown in FIG. 27B. In step ST45, the controller MC controls the transfer robot LMR to transfer the ring 222R from the support member SP42 to the handler of the transfer robot LMR.

In step ST45, the ring 222R is transferred into the replacing module RM4 as shown in FIG. 27C. In step ST45, the controller MC controls the transfer robot LMR to transfer the ring 222R into the replacing module RM4.

In step ST45, the lift pins PN in the lifter LU are raised. The ring 222R is thus transferred from the handler of the transfer robot LMR to the lift pins PN as shown in FIG. 28A. The transfer robot LMR then retracts. In step ST45, the controller MC controls the transfer robot LMR and the lifter LU to transfer the ring 222R from the handler of the transfer robot LMR to the lift pins PN.

In step ST45, the handler of the transfer robot TMR then advances into an area below the first ring 221 as shown in FIG. 28B. The lift pins PN are then lowered as shown in FIG. 28C. The first ring 221 and the ring 222R are transferred from the lift pins PN to the handler of the transfer robot TMR. The replacement edge ring 22R including the first ring 221 and the ring 222R is thus provided on the handler of the transfer robot TMR. In step ST45, the controller MC controls the transfer robot TMR and the lifter LU to provide the replacement edge ring 22R on the handler of the transfer robot TMR.

In subsequent step ST46, the replacement edge ring 22R is transferred from the replacing module RM4 into the process module PM by the transfer robot TMR. In step ST46, the controller MC controls the transfer robot TMR to transfer the replacement edge ring 22R.

In step ST46, the replacement edge ring 22R is transferred from the handler of the transfer robot TMR to the lift pins 72 in the lifter 70 in the process module PM. The replacement edge ring 22R is then placed onto the substrate support 16. The controller MC controls the transfer robot TMR and the lifter 70 for this operation.

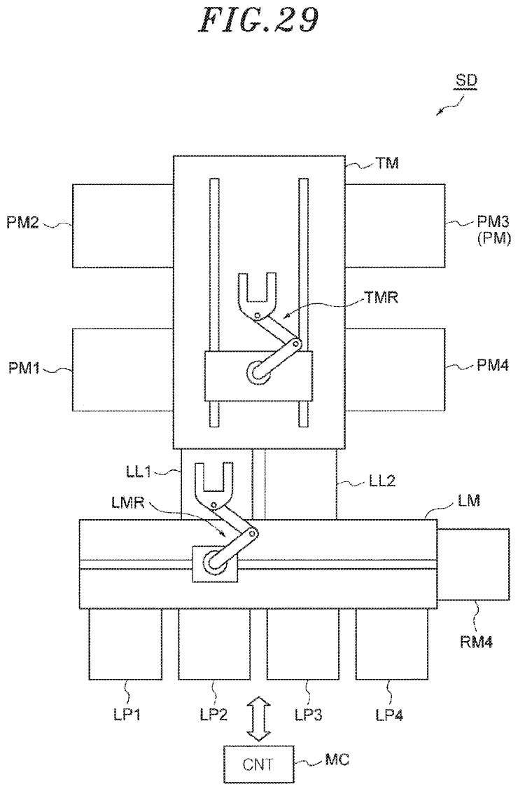

FIG. 29 is a diagram of a substrate processing system according to still another exemplary embodiment. In a substrate processing system shown in FIG. 29 (hereinafter referred to as the system SD), another module different from the loadlock modules LL1 and LL2 serves as the replacing module RM4, and this module is connected to the loader module LM. Other components of the system SD may be identical to those in the system SC.

The method MT4 is also used by the system SD. The method MT4 used by the system SD will be described focusing on its differences from the method MT4 used by the system SC. In step ST42, the edge ring 22 is transferred from the process module PM into either the loadlock module LL1 or LL2 by the transfer robot TMR. The edge ring 22 is then transferred from one of the loadlock modules into the replacing module RM4 by the transfer robot LMR.

In step ST45, a replacement edge ring 22R is provided on the handler of the transfer robot LMR. In step ST46, the replacement edge ring 22R is transferred from the replacing module RM4 into either the loadlock module LL1 or LL2 by the transfer robot LMR. The replacement edge ring 22R is then transferred from one of the loadlock modules into the process module PM by the transfer robot TMR.

The system SC and the system SD may replace, with the replacing module RM4, the edge ring 22 with the replacement edge ring 22R, which is an assembly of the ring 221R and the ring 222R.

In the embodiments described above, both the first ring 221 and the second ring 222 are transferred from the process module PM into the replacing module. At least one of the first ring 221 or the second ring 222 included in the edge ring is thus replaceable in the replacing module.

Although the exemplary embodiments have been described above, the embodiments are not restrictive, and various additions, omissions, substitutions, and changes may be made. The components in the different exemplary embodiments may be combined to form another exemplary embodiment.

For example, the plasma processing apparatus used as the process module in the substrate processing system is not limited to the plasma processing apparatus 1. For example, any type of plasma processing apparatus including the substrate support 16 may be used as the process module in the substrate processing system. The plasma processing apparatus may be another capacitively coupled plasma processing apparatus different from the plasma processing apparatus 1. In some embodiments, the plasma processing apparatus may be an inductively coupled plasma processing apparatus, or a plasma processing apparatus that generates plasma using surface waves such as microwaves.

The process module may include two or more lifters that lift the first ring 221 and the second ring 222 separately or together. Lifting together herein includes the state of having been lifted together, in addition to the action of lifting together.

The exemplary embodiments according to the present disclosure have been described by way of example, and various changes may be made without departing from the scope and spirit of the present disclosure. The exemplary embodiments disclosed above are thus not restrictive, and the true scope and spirit of the present disclosure is defined by the appended claims.

1. A substrate processing system, comprising:
a process module configured to process a substrate, the process module including
a chamber, and
a substrate support configured to support an edge ring including a first ring and a second ring placed on the first ring, the substrate support being configured to support the substrate placed in an area on the substrate support surrounded by the edge ring, the substrate support including at least one lifter configured to lift the first ring and the second ring together;
a transfer robot configured to transfer the edge ring;
a replacing module configured to replace at least one of the first ring or the second ring included in the edge ring with a replacement part to prepare a replacement edge ring; and
a controller configured to control the at least one lifter and the transfer robot,
wherein the controller controls the at least one lifter to lift the edge ring from the substrate support, and controls the transfer robot to transfer the edge ring lifted by the at least one lifter between the process module and the replacing module and to transfer the replacement edge ring prepared in the replacing module between the replacing module and the process module.

2. The substrate processing system according to claim 1, further comprising:
a transfer module connected between the process module and the replacing module, the transfer module being configured to transfer the edge ring with the transfer robot through a chamber that is decompressed.

3. The substrate processing system according to claim 2, further comprising:
a loadlock module connected to the transfer module;
a loader module configured to transfer the edge ring through a housing having an atmospheric pressure; and
a load port connected to the loader module,
wherein the replacing module includes a lifter configured to lift the second ring above the first ring, and
the controller controls the lifter included in the replacing module to lift the second ring included in the edge ring transferred into the replacing module above the first ring included in the edge ring,
controls the transfer robot to transfer the second ring lifted by the lifter included in the replacing module into the loadlock module,
controls the loader module to transfer the second ring transferred into the loadlock module to the load port, and
controls the transfer robot to transfer the replacement edge ring prepared by the second ring being replaced with a replacement part in the replacing module between the replacing module and the process module.

4. The substrate processing system according to claim 2, wherein the replacing module includes
a lifter configured to lift the second ring above the first ring,
a first storage area configured to store the second ring included in the edge ring transferred from the process module, and
a second storage area configured to store a replacement part to replace the second ring, and
the controller controls the lifter included in the replacing module to lift the second ring included in the edge ring transferred into the transfer module above the first ring included in the edge ring, and
controls the transfer robot to store the second ring lifted by the lifter included in the replacing module into the first storage area and to transfer the replacement edge ring including the first ring included in the edge ring transferred into the replacing module and the replacement part retrieved from the second storage area between the replacing module and the process module.

5. The substrate processing system according to claim 1, wherein the replacing module is directly connected to the process module.

6. The substrate processing system according to claim 5, wherein the replacing module includes
a lifter configured to lift the second ring above the first ring,
a first storage area configured to store the second ring included in the edge ring transferred from the process module, and
a second storage area configured to store a replacement part to replace the second ring, and
the controller controls the lifter included in the replacing module to lift the second ring included in the edge ring transferred into the transfer module above the first ring included in the edge ring, and
controls the transfer robot to store the second ring lifted by the lifter included in the replacing module into the first storage area and to transfer the replacement edge ring including the first ring included in the edge ring transferred into the replacing module and the replacement part retrieved from the second storage area between the replacing module and the process module.

7. The substrate processing system according to claim 4, wherein the replacing module further includes
a third storage area configured to store the first ring included in the edge ring transferred from the process module, and
a fourth storage area configured to store a replacement part to replace the first ring, and
the controller controls the lifter included in the replacing module to lift the second ring included in the edge ring transferred into the transfer module above the first ring included in the edge ring, and
controls the transfer robot to store the second ring lifted by the lifter included in the replacing module into the first storage area, to store the first ring included in the edge ring transferred into the replacing module into the third storage area, and to transfer the replacement edge ring including the replacement part retrieved from the fourth storage area and one of the second ring stored in the first storage area or the replacement part retrieved from the second storage area between the replacing module and the process module.

8. The substrate processing system according to claim 6, wherein the replacing module further includes
a third storage area configured to store the first ring included in the edge ring transferred from the process module, and
a fourth storage area configured to store a replacement part to replace the first ring, and
the controller controls the lifter included in the replacing module to lift the second ring included in the edge ring transferred into the transfer module above the first ring included in the edge ring, and
controls the transfer robot to store the second ring lifted by the lifter included in the replacing module into the first storage area, to store the first ring included in the edge ring transferred into the replacing module into the third storage area, and to transfer the replacement edge ring including the replacement part retrieved from the fourth storage area and one of the second ring stored in the first storage area or the replacement part retrieved from the second storage area between the replacing module and the process module.

9. The substrate processing system according to claim 2, further comprising:
a loader module configured to transfer the edge ring through a housing having an atmospheric pressure; and
a load port connected to the loader module,
wherein the replacing module is a loadlock module including a lifter configured to lift the second ring above the first ring and connected to the transfer module,
the load port includes
a first storage area configured to store the second ring included in the edge ring transferred from the process module, and
a second storage area configured to store a replacement part to replace the second ring, and
the controller controls the lifter included in the replacing module to lift the second ring included in the edge ring transferred into the replacing module above the first ring included in the edge ring,
controls the loader module to store the second ring lifted by the lifter included in the replacing module into the first storage area and to transfer the replacement part from the second storage area into the replacing module, and
controls the transfer robot to transfer the replacement edge ring including the first ring included in the edge ring transferred into the replacing module and the replacement part transferred from the second storage area between the replacing module and the process module.

10. The substrate processing system according to claim 2, further comprising:
a loadlock module connected to the transfer module; and
a loader module configured to transfer the edge ring through a housing having an atmospheric pressure,
wherein the replacing module is connected to the loader module and includes
a lifter configured to lift the second ring above the first ring,
a first storage area configured to store the second ring included in the edge ring transferred from the process module, and
a second storage area configured to store a replacement part to replace the second ring, and
the controller controls the lifter included in the replacing module to lift the second ring included in the edge ring transferred into the transfer module above the first ring included in the edge ring,
controls the loader module to store the second ring lifted by the lifter included in the replacing module into the first storage area, and
controls the transfer robot to transfer the replacement edge ring including the first ring included in the edge ring transferred into the replacing module and the replacement part retrieved from the second storage area between the replacing module and the process module.

11. A method for replacing an edge ring, comprising:
lifting an edge ring including a first ring and a second ring from a substrate support with at least one lifter in a chamber in a process module;
transferring the edge ring lifted by the at least one lifter between the process module and a replacing module with a transfer robot;
replacing at least one of the first ring or the second ring included in the edge ring with a replacement part to prepare a replacement edge ring in the replacing module; and
transferring the replacement edge ring between the replacing module and the process module with the transfer robot.
